(19) United States
(12) Patent Application Publication
(10) Pub. No.: US 2025/0125607 A1
(43) Pub. Date: Apr. 17, 2025

(54) DESATURATION CONFIGURATIONS FOR POWER DEVICES

(71) Applicant: ALPITRONIC SRL, Bolzano (IT)

(72) Inventors: Johannes Locher, Eppan (IT); Andreas Oberrauch, Eppan (IT); Alessandro Ciceri, Eppan (IT); Tizian Senoner, Eppan (IT)

(73) Assignee: ALPITRONIC SRL, Bolzano (IT)

(21) Appl. No.: 18/915,629

(22) Filed: Oct. 15, 2024

Related U.S. Application Data
(60) Provisional application No. 63/544,197, filed on Oct. 15, 2023.

(51) Int. Cl. H02H 3/20

(52) U.S. Cl. CPC H02H 3/20

(57) ABSTRACT

A protection circuit with fast responses and high noise immunity includes values of components in the protection circuit determined based on a circuit model of the protection circuit for specific power devices. Further, the circuit model includes overcurrent fault detection criterion based on a maximum current and voltage across power device, together with the transient response of the power device. The protection circuit includes an additional current source when used with a gate driver circuit having a built-in current source. The protection circuit further includes a precharged circuit configured to set the monitored voltage at a base voltage close to the threshold voltage to improve the fault detection responses with a smaller tolerance gap in voltage.

### CROSS-REFERENCE TO RELATED APPLICATION

This application claims benefit under 35 U.S.C. § 119 (e) to U.S. Provisional Application No. 63/544,197, filed Oct. 15, 2023, entitled “DESATURATION CONFIGURATIONS FOR POWER DEVICES,” the entire disclosure of which is hereby incorporated by reference herein.

### BACKGROUND OF THE INVENTION

This invention relates to the field of electric vehicle (EV) charging equipment and more specifically to desaturation circuit configurations for power devices with high noise immunity, independent of current gradient, based on maximum current and voltage, and fast detection.

Semiconductor device manufacturers are continually pushing the boundaries of power loss and switching time improvements for power devices, while requiring high reliability and robustness. For example, the ever increasing efficiency requirements have pushed the limits of these DC-DC converter topologies to be above 95%, or close to 98%. Furthermore the requirements for high output power have reached charging currents of more than 100 Amps, which requires a high efficiency just to keep the charger from overheating.

With demand for power devices having high efficiency together with increased reliability and robustness, the gate driver design for these power devices, such as Silicon Insulated Gate Bipolar Transistor (Si IGBT) or Silicon Carbide Metal Oxide Semiconductor Field Effect Transistors (SIC MOSFET), is challenging and crucial, in which the overcurrent or short circuit protection is an indispensable function for system reliability, both in terms of device destruction and system safety. Short-circuit faults are the most critical failure mechanism in power converters, which can be caused by controller faults, device breakdowns, or load short circuits. Due to the excessive power dissipation during the short-circuit transient, the device junction temperature can exceed the limit and lead to a permanent failure of thermal runaway or explosion.

The short circuit protection for IGBT has been extensively investigated, with multiple short circuit protection schemes developed for IGBT, including desaturation detection, shunt resistor sensing scheme, and senseFET current sensing. Due to the relatively long short-circuit withstand capability of IGBT devices, which is the amount of time from the start of short circuit fault until the time the device is completely damaged, the present protection schemes works for IGBT devices.

Compared with Si IGBT, SiC MOSFET has lower thermal dissipation capability, which leads to a smaller short circuit withstand capability, due to the smaller chip size and higher current density. SiC MOSFET also shows a higher surge current due to the short channel effect. Thus, a protection scheme for SiC MOSFET requires at least a faster response speed.

With more and more SiC MOSFETs used in power converters to improve the efficiency and power density, there is a need for fast protection circuits with an ability of accommodate high surge current. Further, since the short circuit withstand time can vary widely from device to device, the protection circuit should also take into account the individual device characteristics.

### SUMMARY OF THE EMBODIMENTS

In some embodiments, the present invention discloses a protection circuit that can offers fast responses with high noise immunity suitable for high switching power devices such as Silicon Carbide Metal Oxide Semiconductor Field Effect Transistors (SiC MOSFET).

Components of the protection circuit can be determined based on a circuit model of the protection circuit for specific power devices, e.g., by using device parameters such as parasitic inductance Los and ON state resistance R_{DS} of the power device in the circuit model. Overcurrent fault detections in the protection circuit are based on predetermined constraints, such as constraints of a maximum current Iₘₐₓ through power device and a maximum voltage Vₘₐₓ across power device. The circuit model also considers the transient response of the power device, which can ensure that there is no false triggering during the fast switching transient, for example, by di/dt monitoring using Los. As a result, the protection circuit can operate independent of the current gradient, together with preset values of maximum current and voltage.

With the inclusion of values of the parameters of the power device in the protection model, the protection circuit can provide a fast detection response without being concern with additional margin due to variations in different power devices.

In some embodiments, the protection circuit includes a high current source, e.g., higher than the current source in a gate driver circuit used for Si IGBT devices. Thus, when the protection circuit is used with a gate driver circuit having a built-in current source, an additional current source is provided externally to the gate driver circuit to generate the desired value of the current required by the protection circuit.

In some embodiments, the additional current source can be configured as a current mirror, which serves as a simple current regulator, supplying a nearly constant current to a load over a wide range of load resistances. The regulated current through the current mirror configuration can be adjusted by adjusting the resistors in the current mirror configuration. A one-way element, such as a diode, can be added to the output of the current mirror configuration, to decouple the current mirror from the load.

The current mirror configuration can provide a low cost and simple current source to generate enough extra current to linearly charge the blanking capacitor independently of the gate driver IC.

In some embodiments, the protection circuit further includes a precharged circuit configured to set the monitored voltage at a base voltage close to the threshold voltage, e.g., close to the voltage at which the short-circuit fault detection is activated. In addition to an additional current source, which is configured to increase the charging speed of the blanking capacitor, the new base voltage can further improve the fault detection responses with a smaller gap in voltage. For example, the precharged circuit can be configured to provide a tolerance level at less than 4 V or less than 3 V, depending on the power device module.

The precharged circuit is coupled to the protection circuit using a one-way circuit, such as a diode. The one-way circuit is configured to set the base voltage at a desired level, and is decoupled from the protection circuit when the monitored voltage increases. With the one-way circuit, the precharged circuit can provide an adjustable base voltage while not interfering with the protection operation of the protection circuit.

In some embodiments, the precharged circuit can include a voltage source, such as a Zener based voltage source, coupled to a diode. A low resistor is coupled to the Zener diode to allow a fast voltage response to the Zener voltage, for example, from an off state.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Further, the claimed subject matter is not limited to implementations that solve any or all disadvantages noted in the Background.

### BRIEF DESCRIPTION OF THE DRAWINGS

FIGS. 1A-1B illustrate configurations of a charger according to some embodiments.

FIGS. 2A-2B illustrate a schematic and operation waveforms of a desaturation protection circuit for a Si IGBT power device according to some embodiments.

FIGS. 3A-3C illustrate a concept for a protection circuit for a power device including SiC MOSFET according to some embodiments.

FIGS. 4A-4B illustrate a protection circuit model for a SiC MOSFET according to some embodiments.

FIGS. 5A-5B illustrate algorithm schematics for determining components of a protection circuit according to some embodiments.

FIG. 6A-6C illustrate flow charts for forming a protection circuit for a power device according to some embodiments.

FIGS. 7A-7C illustrate configurations of a protection circuit according to some embodiments.

FIGS. 8A-8B illustrate flow charts for forming a protection circuit having a current source, with the protection circuit configured to work with a gate driver circuit already having another current source according to some embodiments.

FIGS. 9A-9B illustrate flow charts for forming a protection circuit having a current source, with the protection circuit configured to work with a gate driver circuit not having a current source according to some embodiments.

FIGS. 10A-10B illustrate flow charts for forming a protection circuit not having any current source, with the protection circuit configured to work with a gate driver circuit having a current source according to some embodiments.

FIGS. 11A-11B illustrate a mirror configuration for a current source in a protection circuit according to some embodiments.

FIGS. 12A-12B illustrate flow charts for forming a protection circuit having a mirror configuration current source according to some embodiments.

FIGS. 13A-13B illustrate a protection circuit having a precharged circuit according to some embodiments.

FIGS. 14A-14C show flow charts for forming a protection circuit having a precharged circuit according to some embodiments.

FIGS. 15A-15B illustrate a configuration of a precharged circuit according to some embodiments.

FIGS. 16A-16B show flow charts for forming a protection circuit having a Zener diode precharged circuit according to some embodiments.

FIGS. 17A-17B illustrate configurations for a protection circuit together with a gate driver circuit for a power device according to some embodiments.

FIG. 18 illustrates a flow chart for forming a protection circuit together with a gate driver circuit for a power device according to some embodiments.

### DETAILED DESCRIPTION OF THE EMBODIMENTS

In some embodiments, the present invention discloses a protection circuit for power devices, including Silicon Carbide Metal Oxide Semiconductor Field Effect Transistors (SiC MOSFET), which can offers high noise immunity, including no false triggering during fast switching transient. In addition, the protection circuit can use a fault condition evaluation based on maximum current and voltage across the power device, which can provide fast short circuit fault detection.

Compared to Silicon Insulated Gate Bipolar Transistor (Si IGBT) devices, overcurrent protection of SiC MOSFETs requires a faster response speed due to the smaller chip size and higher current density, which leads to a lower thermal dissipation capability. The protection circuit is designed to respond to a fault faster than a potential destruction and/or degradation of the power device.

### Noise Immunity

An aspect of the protection circuit is a selection of high value blanking capacitor. Since the blanking capacitor is a component of a low pass filter for noise, higher value blanking capacitor can provide better noise immunity protection, such as from noises resulting from the high dv/dt and di/dt switching transients. For example, the blanking capacitor can be selected to have a capacitance of higher than 100 pF, higher than 150 pF, higher than 200 pF, and can be in a vicinity of 220 pF.

To offset the lower charging time of a high value blanking capacitor, a high current source can be used in the protection circuit to quickly charge the blanking capacitor when a fault condition is detected. The value of the current source can be determined after a selection of a high value blanking capacitor, to ensure a fast fault response time together with a high noise immunity.

Fast Switch Transient di/dt

The noise immunity can also be further achieved in the protection circuit to provide no false triggering during fast switching transient. An issue under the short-circuit fault is the high di/dt at the rapid turn-off transient, which may lead to a large voltage overshoot because of the effect of stray or parasitic inductance. For example, at low voltage and high current operating conditions, the voltage induced by the parasitic inductance, e.g., L_{DS}×di/dt can have a relevant influence on the short circuit detection threshold. The fault condition evaluation in the protection circuit design thus includes a detection of an overcurrent/short circuit fault by di/dt monitoring; using an inclusion of parasitic inductance L_{DS} of the power device in the circuit model of the protection circuit. With a proper selection of components in the protection circuit, the protection circuit can operate independent of the current gradient, e.g., the protection circuit can be able to protect power devices, including SiC MOSFETs, in different fast switching conditions.

### Preset Maximum Current And Voltage

Another aspect of the protection circuit is an ability to trigger the fault current mode based on a preset current Iₘₐₓ through the power device, in addition to a preset voltage Vₘₐₓ across the power device. For example, a monitor circuit in a gate driver circuit can be included to monitor a voltage related to a voltage V_{DS} across the source and drain of a SiC MOSFET or to a voltage V_{CE} across the collector and emitter of a Si IGBT. The protection circuit can be designed and the components in the protection circuit can be calculated so that when a current through the power device, such as a current I_{DS} through the source and drain of a SiC MOSFET or a current I_{CE} through the collector and emitter of a Si IGBT, reaches a preset maximum value Iₘₐₓ, for example, the voltage V_{DS} or V_{CE} across the power device increases so that the voltage at the monitor circuit reaches a threshold voltage to trigger the fault condition. The maximum current Iₘₐₓ can be less than 250 A, less than 200 A, less than 150 A, or less than 100 A. The maximum voltage Vₘₐₓ can be less than 15 V or less than 10 V.

The fault condition evaluation in the protection circuit design thus includes fault conditions of a maximum current and a maximum voltage across the power device. With a proper selection of components in the protection circuit, the protection circuit can be triggered when the current or the voltage across the power device reaches the maximum value, e.g., the protection circuit can be able to protect power devices against a surge in current or voltage above preset values.

### Individual Power Devices

Another aspect of the protection circuit is that the protection circuit is individually tailored to the power devices, e.g., to different groups of power devices with each group having same or similar characteristics, such as power devices classified under a same name. Values of the components in the protection circuit are determined from a circuit model of the protection circuit using the parameters of the power device, such as the Drain-to-Source On resistance R_{DSon} and Drain-to-Source inductance L_{DS}, which can be obtained from the device datasheet or from direct measurements from the device.

With the protection circuit designed for the individual power devices, the fault condition evaluation in the protection circuit is determined based on the power device that the protection circuit protects. As such, there can be no need to build in additional margin beyond the specified short circuit fault conditions.

### Soft Turn Off

The gate driver circuit for the power device can provide a gradual transition to OFF status to suppress a voltage overshoot during the turn-off transient.

### Charger

In some embodiments, the protection circuit can be used for power devices in power converter circuits in a charger for electric vehicles, e.g., in a power conversion module configured to receive power from a grid such as AC power, and to convert the receive AC power to DC power suitable to charge the electric vehicles. A primary function of the charger is to recharge batteries from the electricity available on an electrical distribution grid. The charger thus includes an alternate current to direct current (AC-DC) converter configured to be coupled to the grid having one phase or three phase output. The AC-DC converter is coupled to one or more direct current to direct current (DC/DC) converters configured to generate a variable DC output range. The charger exhibits a high efficiency, a low bulk, good galvanic insulation, good reliability, high operating safety, a low emission of electromagnetic disruptions, and a low harmonic ratio on the input current.

The charger can be configured to provide a broad output at the vehicle side for handling electric vehicles with different battery voltages, such as battery voltages in a voltage range of 50V-1000V. The charger can be designed to have high efficiency at most of the voltages in the voltage range, and acceptable efficiency at other voltage values. For example, the values of the charger efficiency can be based on the popularity of the electric vehicles, such as based on a probability distribution of battery voltage values for available electric vehicles. For example, there are few electric vehicles with battery voltages in a voltage range of 50V-150V, so the charger can be designed to have higher efficiency at the voltage range of 150V-1000V.

To improve the efficiency, the charger can include a variable transformer. In DC-DC converters, such as dual active bridge (DAB) converter, high efficiency can be achieved when the ratio of Vout over Vin in the DC-DC converter is close to unity. In the case of an isolated DC-DC converter using a transformer, the high efficiency can be achieved when the ratio of Vout/Vin is close to the transformer winding ratio n, with n being the ratio of the primary winding, e.g., the input side of the DC-DC converter, over the secondary winding, e.g., the output side of the DC-DC converter.

For practical reasons, e.g., for simplicity and cost effective designs, the charger can have a transformer with two winding ratios, which can effectively partition the output voltage range into two subranges with equal efficiency using a same DC input voltage range. For example, for an input voltage range of 500V-1000V to the DC-DC converter, the output voltage range of 50V-1000V can be partitioned into two subranges of 50V-500V and 500V-1000V. Using two transformer ratios of 1:1 and 2:1, the battery voltage ranges of 250V-500V and 500V-1000V have similar efficiency. And, as discussed above, fewer electric vehicles have battery voltages in the subrange of 50V-250V, and thus, low efficiency at this subrange presents a const effective solution for the charger.

For example, the transformer can include two sets of primary winding and also two sets of secondary windings, with each winding having a same number of turns. The two primary sets of windings are connected in series. When the two sets of secondary windings are connected in series, the transformer provides a ratio of 1:1. When the two sets of secondary windings are connected in parallel, the transformer provides a ratio of 2:1.

The DC input voltage range can be reduced, for example, to 600V-900V, to improve an efficiency of an AC-DC converter, which is used in the charger to convert an AC voltage from the grid to the DC input voltage. Using a transformer ratio of 1:1, the battery voltage range of 600V-900V can have high efficiency due to a unity voltage gain of the DC-DC converter. The battery DC voltage ranges of 500V-600V and 900V-1000V can have a little lower efficiency due to the deviation of the voltage gain from unity. Advanced switching schemes can be used to improve the efficiency in these voltage ranges.

Using a transformer ratio of 2:1, the battery voltage range of 250V-500V can be similar, e.g., having similar efficiency. For example, the voltage range of 300V-450V can have high efficiency since the voltage gain is close to the transformer ratio. The voltage ranges of 250V-300V, and the voltage range of 450V-500V can have a little lower efficiency, which can be improved using advanced switching schemes. In addition, the voltage range of 50V-250V can be partitioned into two subranges, such as 50V-150V and 150V to 250V. The subrange of 150V-250V can have acceptable efficiency, since the deviation of the voltage gain to the transformer ratio is not excessively large. Thus, the voltage subrange of 150V-250V can be treated as the voltage range of 250V-300V.

For the voltage subrange of 50V-150V, since the deviation of the voltage gain to the transformer ratio is larger than 2, the switching frequency of the DC-DC converter can be doubled to reduce the peak current in the semiconductor and the transformer, including the magnetic flux) in the DC-DC converter. The efficiency is a little lower than other battery voltage ranges, but with a low probability of electric vehicles having this battery voltage range, it can be a cost effective solution in an attempt to provide charger services to as many electric vehicles as possible.

The charger can be configured allow measuring the battery voltage of the electric vehicle coupled to the charger. For example, an output of the DC-DC converter can be coupled to a terminal of a controllable switch, such as a relay or a MOSFET. The other terminal of the controllable switch is configured to be coupled to the electric vehicle, such as a coupling to a handle of the charger. In operation, the charger handle is coupled to the electric vehicle, and the battery voltage of the electric vehicle can be measured, for example, by turning off the controllable switch. In practice, the controllable switch is normally off, which can serve as a safety feature for the charger. Thus, the vehicle battery voltage can be measured after the charger handle is coupled to the electric vehicle. After the charger is ready to charge the electric vehicle, for example, after selecting the appropriate transformer ratio, after setting the switching signal for the AC-DC converter to generate appropriate DC input voltage to the DC-DC converter, and after setting the switching signal for the DC-DC converter such as setting the appropriate switching frequency, the controllable switch can be turned on to start charging the electric vehicle. During charging, feedback voltage from the vehicle battery can be used to control the charging characteristics, such as characteristics of the switching signals for the AC-DC converter or for the DC-DC converter.

The charger can include a controller, configured to obtain a voltage of an electric vehicle coupled to the charger. The controller is also configured to control the transformer ratio, the switching signal of the AC-DC converter, and the switching signal of the DC-DC converter based on the obtained voltage. The controller is further configured to control the controllable switch, such as to turn on the controllable switch after the charger conditions are set, and to turn off the controllable switch after the charger finishes charging the electric vehicle. The controller is also configured to regulate the switching signal of the AC-DC converter, and the switching signal of the DC-DC converter to provide an appropriate charging current to the electric vehicle during the charging session.

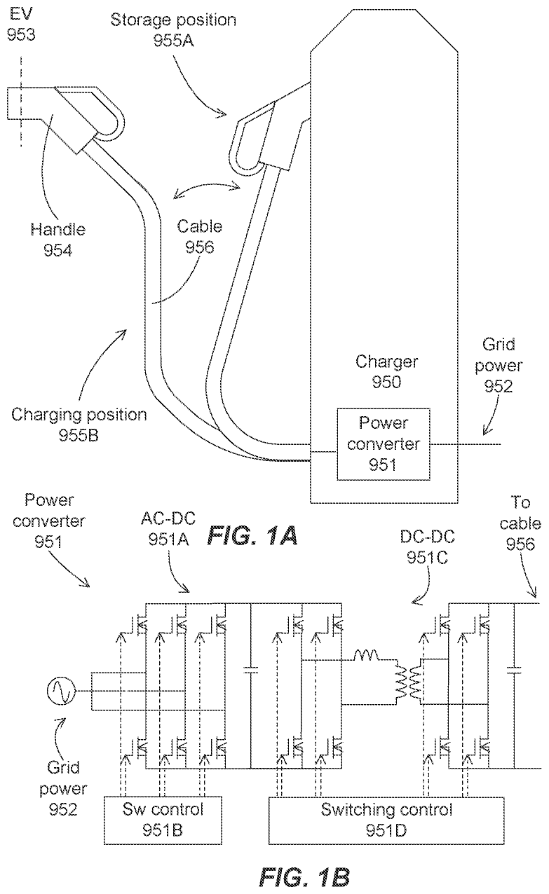

FIGS. 1A-1B illustrate configurations of a charger according to some embodiments. FIG. 1A shows a charger 950 configured with a cable 956 for carrying electrical currents to electric vehicles 953. At one end of each cable, there is a connector having a handle 954. The connector is designed so as to be compatible with a charging inlet or socket on an electric vehicle, and can therefore be configured according to one or more standards for electric connectors. The handle is designed for a user to handle the charging cable, such as to remove the cable from a storage position 955A to a charging position 955B to charge the electric vehicle. The other end of the cable opposite the handle is assembled into a body of the charger, such as to connect the electrical conduits in the cable with the power converter module 951. The power converter module 951 includes at least an output, which is coupled to the electrical conduit to the handle 954. The power converter module 951 can be coupled to a grid power 952, to receive power from the grid to be converted to a DC power to charge the battery of the electric vehicle.

The cable with the handle can normally be positioned in a storage position 955A, in which the handle is housed in a handle holder in the charger. An electric vehicle 953 can be positioned near the charger to have its battery charged. When the electric vehicle 953 is ready, the handle is removed from the handle holder, to be coupled with the socket of the electric vehicle, in a charging position 955B. The cable is typically long enough to allow the electric vehicle to park at a distance less than the length of the cable, to be reached by the cable.

For example, the charger can be designed for one or more types of electric vehicles, such as a charger installed at a private or public location. A charging cable 956 is shown to connect the charger 950 with the electric vehicle 953. One end of the charging cable is permanently attached to the charger. At the time of charging, a user removes the charging cable at the handle to attach the handle to the socket, e.g., a charge port of the electric vehicle.

The charger, which is also called an electric vehicle supply equipment EVSE, can be used to charge a battery, such as a battery in an electric vehicle. The electric vehicles can include electric cars, neighborhood electric vehicles, fork lifts, plug-in hybrids, or any moving system having an operating battery.

The charger can include a power converter module 951, which is configured to receive electric power from an external power supply, such as from a generator or an electric grid 952, which can be 340-550 VAC, 1 to 3 phases. The power converter unit then conditions the supplied power so as to deliver the proper electric energy to the electric vehicle, e.g., converting the grid power to a voltage suitable to charge the battery of the electric vehicle, which can be 50-1000 VDC, depending on the batteries of the electric vehicle connected to the charger. For example, incoming AC power from the grid can be converted to a suitable form of DC for direct charging the battery. The cable can include a ground conductor, which can be connected to a ground terminal in the charger. During charging, the ground conductor can be connected to a corresponding ground terminal in the electric vehicle, such as to the vehicle chassis.

Each electric vehicle has a battery having a defined rated voltage. For example, an electric vehicle having a 400V-battery can accept a charging DC voltage range of about 300V to 450V, and an electric vehicle having an 800V-battery can accept a charging DC voltage range of about 600V to 850V. At present, the popular rated voltage for batteries of electric vehicles is 400 V-800V, but electric vehicles having different battery voltages are also known, such as a limited number of electric vehicles having a battery voltage in the range of 50V-150V. Higher battery voltages, such as a battery having a rated voltage of 800V, can provide a higher power density, such as than a battery having a rated voltage of 400V, of the same size. Further, higher battery voltages can result in lower current, leading to a reduction in the size of the current carrying conductors.

The charger can be installed in public space such as parking lots or at private premises. Each charger can be equipped with one or two charging cables, with each cable including a charging connector for interfacing with an electric vehicle. There is a need for rapid charging of the battery of the electric vehicle, e.g., the charging time needs to be so that a user would find it acceptable for waiting for the electric vehicle to be charged. In general, the charging time is governed by the voltage and the amount of current that a charger system can deliver to the battery through the charging cable, which can be a limiting factor for increasing the delivering current.

For rapid charging operations, particularly high currents must be used, e.g., the current generated by the power converter and carried by the electrical conduits in the cable can be high, e.g., above 100 A or 200 A, and can reach 500 A to 1000 A. As such, the charger is designed with high efficiency, such as greater than 90%, greater than 95% or 96%, or about 98% in some cases such as vehicle-to-vehicle (V2V) charging. With high efficiency for a wide range of DC output voltages, together with a cost effective design, the present charger can possess a design innovation for charger configurations.

FIG. 1B shows a schematic for a power conversion module 951. The module include an input power interface being connectable to a power source such as the grid, an AC-DC converter 951A for rectification of the AC voltage from a power grid 952, a DC-DC converter 951C connected to the AC-DC converter for battery current and voltage regulation, and an output power interface connected to the DC-DC-converter and configured to be connected to the battery of the electric vehicle. Other circuits can be included, such as a Power Factor Correction (PFC).

The AC-DC module 951A is configured to be coupled to the grid 952, which can be a single phase or three phase power, providing a fixed voltage, such as 340-550 VAC. The input power interface can include an input switch, which is coupled between the input of the AC-DC converter to the input of the power converter module 951, which can serve to isolate the power converter module from the grid, for example, to turn off the charger. A DC link capacitor can be coupled between the output of the AC-DC converter 951A and the input to the DC-DC converter 951C, for example, to regulate the rectified output voltage from the AC-DC converter.

The output power interface can include an output switch, which is coupled between the output of the DC-DC converter to the output of the power converter module 951, and which can serve to isolate the module from the electric vehicle 953, for example, to measure the battery voltage of the electric vehicle. The DC-DC converter 951C can be configured to deliver a voltage in a range of 50V to 1000V, which is designed to match with the measured battery voltage of the electric vehicle.

The power converter module 951 can include switching control circuits 951B and 951D, which are configured to generate switching signals to control the switches, e.g., the power devices such as Si IGBTs or SiC MOSFETs, of the AC-DC and DC-DC converters. The switching control circuits can include circuits to generate switching signals, together with gate driver circuits for driving the gates of the switches.

### Desaturation Protection

Short-circuit faults are the most critical failure mechanism in power converters. Among multiple short-circuit protection schemes, desaturation protection is the most mature and widely used solution.

Desaturation detection uses the voltage across the power device as a measurement component. A diode is coupled to the power device to ensure that the measured voltage across the power device is only monitored by the detection circuit during normal operation of the power device, e.g., then the power device is ON and the voltage across the power device is low (1-4 V for IGBT, for example).

When a short circuit event occurs, the current through the power device increases to drive the power device out of saturated region and into linear region of operation. This results in a rapid increase in the voltage across the power device. The increased voltage level can be used to indicate the existence of a short circuit, with a threshold level (7-9 V for IGBT, for example) used to indicate the short circuit condition.

An important consideration in implementing desaturation detection is to prevent false detection. For example, in IGBT, during the transition from IGBT off state to IGBT on state, the IGBT is not fully in the saturated state and can trigger fault desaturation detection. A blanking time can be used before the desaturation detection is activated to avoid false detection. A current source charging a blanking capacitor or an RC filter including the blanking capacitor and a blanking resistor can be added to introduce a short time constant into the detection mechanism in improve noise immunity.

After an overcurrent is detected, the power device is turned off to prevent potential damage. Turning off the power device under an overcurrent condition should be more gradual to prevent overvoltage condition across the power device due to parasitic inductance causing di/dt induced voltage.

Under normal operating conditions, the gate driver is designed to turn off the power device as fast as possible to minimize switching losses, for example, by having a low driver impedance and a small gate drive resistance. A higher impedance turn-off path can be used when shutting off the power device during a desaturation event to reduce potentially destructive overvoltage levels.

Thus, a DESAT terminal, e.g., a location configured to provide a voltage related to the voltage across the power device, is monitored constantly to detect power device faults such as short circuits. If the voltage exceeds a standard threshold value, the power device is switched to a soft shutdown mode, e.g., a gradually shut down process as compared to an abrupt switch off in normal operations. The threshold voltage Vₜₕ can be less than 15 V, less than 12 V, or less than 10 V.

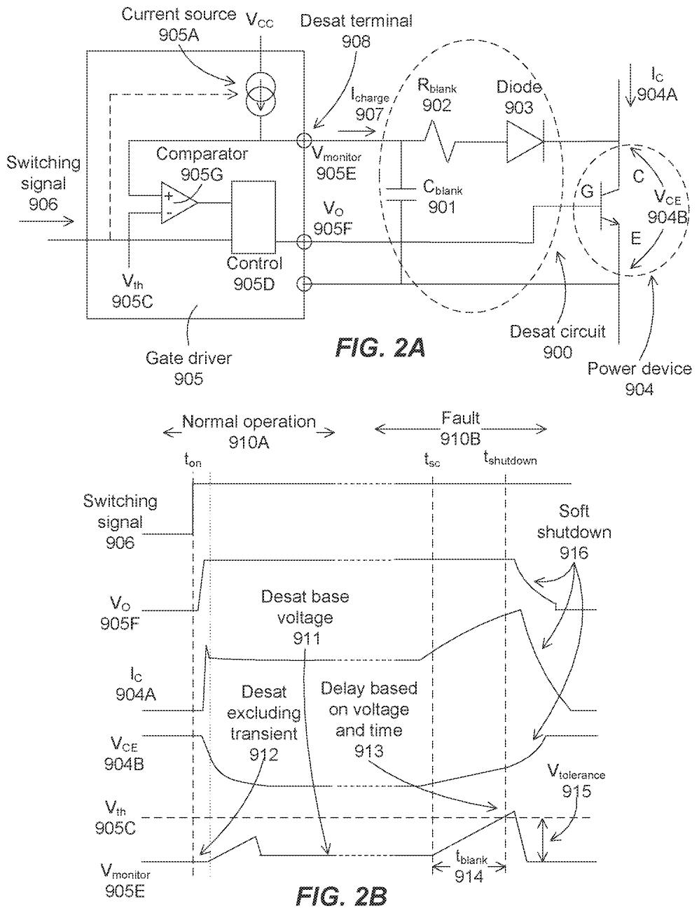

FIGS. 2A-2B illustrate a schematic and operation waveforms of a desaturation protection circuit for a Si IGBT power device according to some embodiments. FIG. 2A shows a desaturation circuit 900 for a Si IGBT power device 904. In general, a desaturation protection circuit monitors a voltage related to the power device while the power device conducts current. When the current becomes excessive, e.g., an overcurrent event such as short circuit event, the protection circuit would detect an increase in the monitored voltage and trigger a safe turn off to the power device.

A voltage 904B across the power device 904, e.g., the voltage V_{CE} between the collector C and the emitter E of the IGBT 904, can be monitored at a desat terminal 907, for example, by a comparator 905G. The comparator 905G is configured to compare the voltage Vₘₒₙᵢₜₒᵣ 905E at the desat terminal 907 with a threshold voltage Vₜₕ 905C, which is a preset reference voltage. Vₘₒₙᵢₜₒᵣ 905E is related to V_{CE}, e.g., the voltage across the collector and emitter of the IGBT. When Vₘₒₙᵢₜₒᵣ 905E exceeds Vₜₕ 905C, the comparator 905G sends a fault signal to the control circuit 905D, which then can send a shut down signal to the power device 904, e.g., to the gate G (or base) of the IGBT 904. The control circuit is configured to receive a switching signal 906, such as a PWM signal, and to send a drive signal V. 905E to the gate G to turn the IGBT on or off. There can be two different components in the control circuit, with one component configured to send an abrupt gate signal for rapidly switching the power device, and the other component configured to send a gradual gate signal for gradually switching, e.g., soft shutting down, the power device.

A desaturation circuit 900 can include a diode 903, a blank resistor 902, a blank capacitor 901, and a current source 905A. The diode 903 is configured to one-way decouple the capacitor 901, the resistor 902, and the current source 905A from the power device 904, e.g., the components of the desaturation circuit 900 is decoupled from the power device when the power device is not in a saturation mode. The diode 903 can be a high voltage diode, and is also configured to protect the gate driver circuit 905 when the power is turned off.

The resistor 902, together with the capacitor 901, forms a low pass filter, which is configured to eliminate noises from the power device. The resistor 902 is also configured to limit the current flowing through the diode 903. The capacitor 901 is also configured to define a filtering time together with the current source 905A. The capacitor 901 is also configured to increase robustness against fault triggering for short term voltage peaks during operation. The current source 905A, controlled by the switching signal 906, is configured to charge the capacitor 901 during the ON time of the power device.

During normal operations, current I_{charge} 907 flows to the capacitor 901 to charge the capacitor and to the resistor 902, the diode 903, and the power device 904, since the voltage V_{CE} is low. At steady state, the voltage at the capacitor 901, e.g., a base voltage of the voltage Vₘₒₙᵢₜₒᵣ 905E, is equals to the sum of the voltage across the diode 903, the voltage across the resistor 902, and the voltage V_{CE} across the power device 904. Thus, the monitored voltage Vₘₒₙᵢₜₒᵣ 905E is higher than V_{CE} by the voltages drop across the diode and across the resistor 903.

When an overcurrent event occurs, the power device is no longer in the saturation state due to an increase of the current I_{C} 904A through the power device. The voltage V_{CE} increases, and the diode 903 is no longer conducting. The current I_{charge} 907 from the current source 905A now flows only to the capacitor 901 to charge the capacitor to a higher voltage than the base voltage at steady voltage. When the voltage Vₘₒₙᵢₜₒᵣ at the capacitor equals to the threshold voltage, the comparator 905G sends a fault signal to the power device to shut down the power device before any potential damage to the power device.

A gate driver circuit 905 can include the comparator 905G, the control circuit 905D, and the current source 905A, with a desat terminal 908 for monitoring the voltage Vₘₒₙᵢₜₒᵣ 905E related to the voltage V_{CE} at the power device, and an output terminal for sending gate signal Vₒ 905F.

Advantages of the desaturation circuit can include a simple circuit with low loss and with a programmable protection time. Multiple high voltage diodes are needed to share blocking voltage for high voltage. e/g., above 1000V, applications.

FIG. 2B shows a timing chart for a switching sequence of the desat circuit. During a normal operation 910A, when the switching signal switches from OFF to ON, for example, at time tₒₙ, the control circuit 905D in the gate driver circuit 905 sends an ON gate signal V. 905F to the gate G of the power device 904, e.g., the gate signal Vₒ 905F switches from OFF to ON at time tₒₙ.

With the power device turned on by the gate signal Vₒ 905F, the current I_{C} 904A through the power device increases and the voltage V_{CE} 904B across the power device drops. The switching signal 906 also turns on the current source 905A, which then charges the capacitor 901. The voltage at the capacitor, e.g., the voltage Vₘₒₙᵢₜₒᵣ 905E, increases due to the charging current from the current source 905A.

When the voltage V_{CE} drops to the saturation voltage V_{CEon}, the diode conducts and the voltage Vₘₒₙᵢₜₒᵣ 905E drops to the base voltage, which is the sum of the voltage drop across the resistor 902, the diode 903, and V_{CEon}.

Before the time t_{sc} of a fault operation, the current I_{C} 904A and the voltage V_{CE} 904B are at a saturation mode. The voltage Vₘₒₙᵢₜₒᵣ 905E is at the base voltage. A fault occurs, causing the current I_{C} and voltage V_{CE} to increase, leading to a reverse bias on the diode 903.

During a fault operation 910B, at time t_{sc}, the current source 905A stops flowing into the power device and flows into the capacitor 901, raising the voltage Vₘₒₙᵢₜₒᵣ 905E across the capacitor. A time t_{shutdown}, when the voltage Vₘₒₙᵢₜₒᵣ 905E reaches the threshold voltage Vₜₕ 905C, the comparator circuit 905G sends a fault signal to the control circuit 905D to shut down the power device. Using a soft shutdown scheme, the current I_{C} and voltage V_{CE} gradually decreases and increase, respectively. The voltage Vₘₒₙᵢₜₒᵣ 905E also drops.

The time t_{blank} between the t_{sc} and t_{shutdown} is configured to be shorter than a short circuit tolerance of the power device, and long enough to avoid erroneous shut down triggering.

The desaturation method, as discussed above, works well for IGBT, but may have limitations for SiC MOSFET, especially when using gate drivers designed for IGBT. The limitations include a slow response time of t_{blank}, which is adequate for IGBT, but can be too long for SiC MOSFET in many cases.

SiC MOSFET has become the potential substitute for Si IGBT for power converter applications because of superior characteristics, including high blocking voltage and high switching frequency. SiC MOSFET has more stringent short circuit protection requirements than Si IGBT due to their higher current density and lower thermal capacitance, and weaker short circuit withstand capability, with the short circuit protection requirements including a fast detection time and a reliable operation without false trigger.

The common short circuit protection schemes include detection of current I_{CE} or I_{DS}, voltage V_{CE} or V_{DS}, current gradient di/dt, gate voltage, or gate charge, which leads desaturation detection scheme, shunt resistor sensing scheme, and senseFET current sensing scheme. Among these schemes, the desaturation technique of detecting the voltage related to V_{CE} or V_{DS} is the most mature and widely used solution, with off-the-shelf IGBT gate driver integrated circuits (IC).

Compared to IGBT with similar blocking voltage and current rating, SiC MOSFET has a smaller chip area, which makes the parasitic capacitance smaller than IGBT and increases the intrinsic switching speed. However, the smaller chip area means the SiC MOSFET die has lower thermal dissipation capability. During short circuit conditions, the surge current generates a significant amount of joule heating and the die can be destroyed in a short period of time without enough capability to dissipate the heat. With a smaller die size, the surge current capability of SiC MOSFET is lower than that of IGBT. Thus, a gate driver IC designed for desat protection for Si IGBT is not reliable enough to protect SiC MOSFET under abnormal conditions.

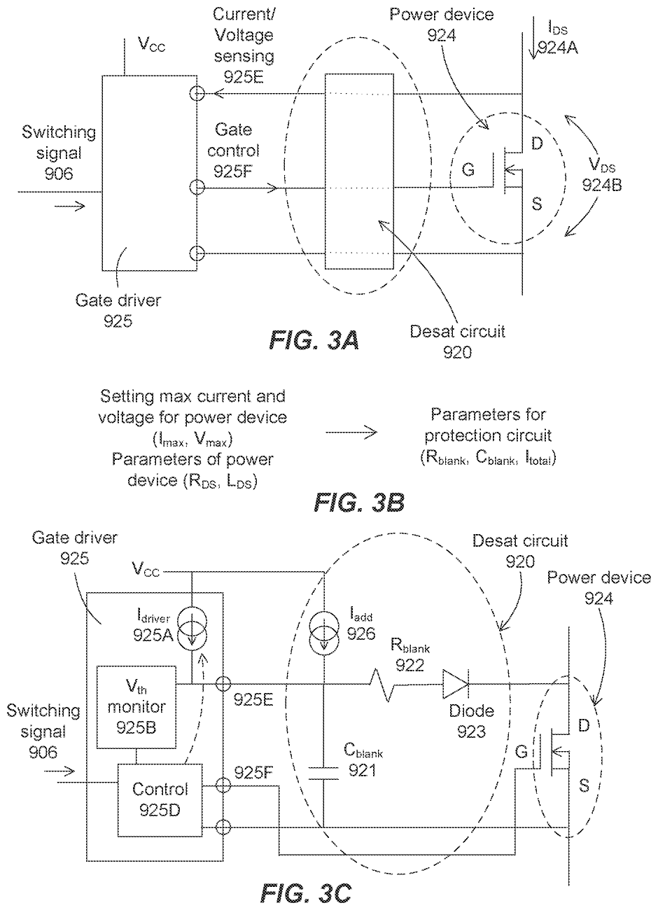

FIGS. 3A-3C illustrate a concept for a protection circuit for a power device including SiC MOSFET according to some embodiments. FIG. 3A shows a block diagram of a protection circuit suitable for a SiC MOSFET. In the diagram, a gate driver 925 based on an off-the-shelf driver IC is used, which includes a current source, a monitor circuit such as a comparator circuit, and a control circuit configured to generate gate signals to drive the gate of a power device. The gate driver 925 includes a first terminal for accepting a voltage input 925E related to the voltage across a power device 924. The first terminal can also be used to provide a current from the current source toward the power device. The gate driver 925 includes a second terminal for transferring gate signals 925F to the power device. The gate driver 925 includes an input configured to receive a switching signal 906, such as a PWM signal for switching the power device. Other inputs can be included, such as a power input Vcc, and a ground input.

A desaturation circuit 920 is coupled to the gate driver 925 and the power device 924 to protect the power device against abnormal conditions, such as overcurrent or short circuit conditions.

FIG. 3B shows a concept for the design of the protection circuit. Components of the protection circuit can be determined based on a circuit model of the protection circuit with the power device and the gate driver circuit, using desired constraints, such as constraints of a maximum current Iₘₐₓ through power device and a maximum voltage Vₘₐₓ across power device for specific power device, e.g., by using parameters R_{DS}, L_{DS} of the power device in the circuit model. The protection circuit thus can trigger a fault overcurrent event with an explicit maximum value of the current through the power device, in addition to an implicit current value based on a maximum voltage value across the power device.

The fault condition evaluation in the protection circuit can include a detection of when the current exceeds a maximum value, using an inclusion of the maximum current value through the power device in the circuit model of the protection circuit. Thus, the protection circuit can be able to protect the power device against a surge in current or voltage above preset values.

The components in the protection circuit can be calculated so that when a current through the power device reaches a preset maximum value Iₘₐₓ, the overcurrent fault condition is trigger to enable a shut down of the power device. For example, a voltage related to the voltage V_{DS} or V_{CE} across the power device is monitored to alert a control circuit to send a shut down signal to the power device when the current reaches or exceeds the maximum value.

The circuit model also considers the transient response of the power device, which can ensure no false triggering during the fast switching transient. The fault condition evaluation in the protection circuit can include a detection of an overcurrent/short circuit fault by di/dt monitoring; using an inclusion of parasitic inductance L_{DS} of the power device in the circuit model of the protection circuit. Thus, with a proper selection of components in the protection circuit, the protection circuit can operate independent of the current gradient, e.g., the protection circuit can be able to protect power devices, including SiC MOSFETs, in different fast switching conditions.

The circuit model also considers the individuality of the power devices. Specific values of the parameters of the power device, such as R_{DSon} and L_{DS}, are used in the protection circuit model. The fault condition evaluation in the protection circuit can include a detection of an overcurrent/short circuit fault using parameters of the power device that the protection circuit is designed to protect. Thus, with a proper selection of components in the protection circuit, the protection circuit can provide a fast detection response without being concern with extra margin due to variations in different power devices, e.g., there is no potential mis-triggering the protection circuit due to a too-fast response, or there is no potential damage to the power device due to not-fast-enough response because of a large margin of safety.

The components of the protection circuit can be selected for high noise immunity. For example, the capacitor value can be high to provide a good low pass filter for noise protection.

FIG. 3C shows a schematic of a desaturation protection circuit for a SiC MOSFET. The methodology for a protection circuit is described in the form of a desaturation protection circuit for a SiC MOSFET power device, but the methodology can be applied to other short circuit protection schemes or to other types of power devices.

A desaturation circuit works based on a difference in a voltage drop across the power device. During a normal operation, the power device is in an ON state having a low voltage drop. During an overcurrent event, the voltage drop increases rapidly. Thus, the desaturation circuit is configured to monitor a voltage related to the voltage drop across the power device.

A delay time between the voltage drop and the monitored voltage is introduced through a blanking resistor and capacitor to allow for noise disturbances. Thus, when an overcurrent occurs, there is a time delay, caused by a current source charging the blanking capacitor, before the desaturation circuit sends a gate signal to shut down the power device. The time delay needs to be long enough to avoid false shut down due to noise disturbances. The time delay also needs to be short enough to avoid the danger of a catastrophic failure due to excessive current leading to device overheat.

The desaturation circuit has been widely used for the protection of Si IGBTs, mainly due to a high tolerance of the Si IGBT for overcurrent, which can afford a long delay time to avoid noise-related fault triggering. But the desaturation circuit can be insufficient to protect SiC MOSFET power devices, mainly due to a lower thermal dissipation capability of the SiC MOSFETs, which can reach a dangerous or damaging state before the protection circuit is activated. There are attempts to reduce the time delay in the protection circuit for use with SiC MOSFETs, for example, by reducing the capacitor value or by providing an additional current path to charge the capacitor. However, a straightforward reduction of the time delay is not adequate since transient disturbances and fast switching transient can unnecessarily trip the protection circuit.

In the schematic, a gate driver 925 based on an off-the-shelf driver IC is used, which includes a current source 925A, a monitor circuit 925B such as a comparator circuit, and a control circuit 925D configured to generate gate signals 925F to drive the gate of a power device. The gate driver 925 includes a first terminal for accepting a voltage input 925E related to the voltage across a power device 924. The first terminal can also be used to provide a current from the current source toward the power device. The gate driver 925 includes a second terminal for transferring gate signals 925F to the power device. The gate driver 925 includes an input configured to receive a switching signal 906, such as a PWM signal for switching the power device. Other inputs can be included, such as a power input Vcc, and a ground input.

In some embodiments, the present invention discloses an improved saturation circuit that can be suitable for SiC MOSFETs, as well as for Si IGBT. In the desaturation circuit, the values of the components, such as the current source, the blanking capacitor, and the blanking resistor are tailored to the characteristics of the power device, e.g., different desaturation circuits are used for power devices having different characteristics. In cases that the protection circuit is used with a gate driver circuit having a built-in current source, an additional current source is provided externally to the gate driver circuit to generate the desired value of the current required by the protection circuit.

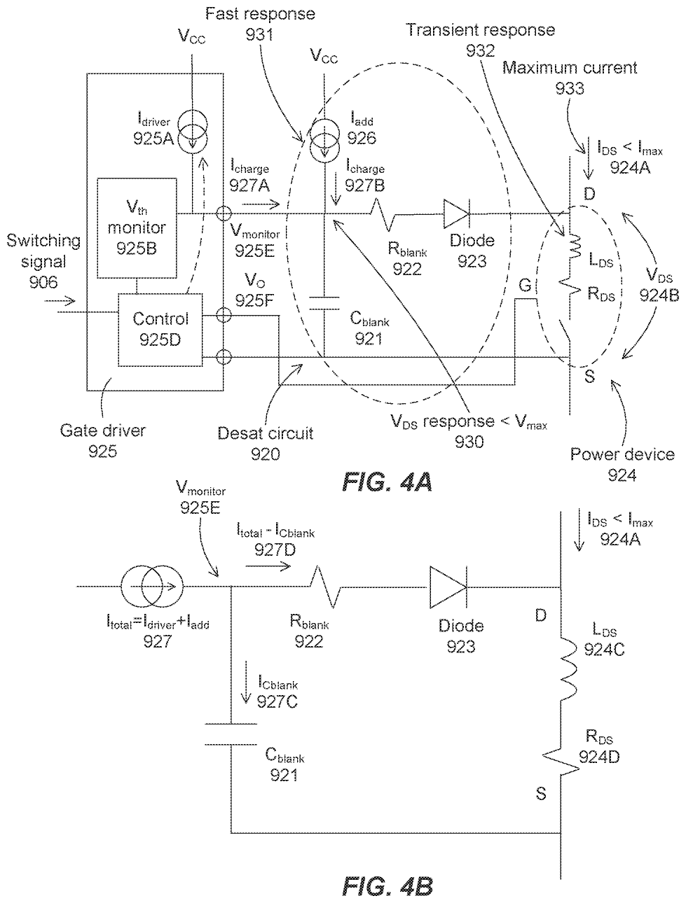

FIGS. 4A-4B illustrate a protection circuit model for a SiC MOSFET according to some embodiments. The components of the desaturation protection circuit can be determined from a circuit model utilizing the parameters of the power device, with the parameters obtained from a datasheet of the power device or from a direct measurement on the power device. With the circuit model containing the parameters of the power device, the desaturation circuit can provide accurate overcurrent fault detection, e.g., enabling fast response without excessive delay margin due to variations in different power devices. For example, using the parasitic source-drain inductance in the desaturation protection circuit model can allow the inclusion of the effect of high current gradient on the overcurrent fault detection, which is necessary since high current gradients in SiC MOSFETs are required to reduce the switching losses. Further, since each module of the SiC MOSFET power device can have a different parasitic inductance, including the parasitic source-drain inductance in the desaturation protection circuit model can allow an accurate overcurrent fault detection.

Thus, the desaturation protection circuit model can provide specific values for each of the components, such as for the blanking capacitor, the blanking resistor, and the additional or total current source in the desaturation protection circuit for each power device in a power switch module.

FIG. 4A shows a desaturation circuit with the SiC MOSFET power device modeled as a parasitic inductance L_{DS} connected to an internal resistance R_{DS}, together with an ideal switch. The desaturation circuit 920 includes current sources 925A and 926 configured to charge a capacitor 921 in parallel with a resistor 922 and the power device 924, with the charging providing a base voltage level indicative of a normal operation of the power device. A diode 923 is included between the resistor 922 and the power device 924 to decouple the power device in the event of an overcurrent condition. When the diode is decoupled from the power device, which indicates an overcurrent event, the current sources can charge the capacitor to a higher voltage. When the voltage reaches a threshold value set by the monitor circuit, a fault condition is triggered and the power device is turned off.

In the desaturation circuit, a gate driver 925 based on an off-the-shelf driver IC is used, which already includes a current source I_{driver} 925A. The gate driver 925 also includes a monitor circuit 925B such as a comparator circuit, which is configured to monitor a voltage Vₘₒₙᵢₜₒᵣ 925E, which is the voltage across the blanking capacitor C_{blank} 921. The current source I_{driver} 925A is also configured to be connected to the blanking capacitor C_{blank} 921, for example, to charge the capacitor with current I_{charge} 927A. The voltage Vₘₒₙᵢₜₒᵣ 925E is related to the voltage across the power device, such as to the voltage V_{DS} of a SiC MOSFET. The monitoring of Vₘₒₙᵢₜₒᵣ 925E can allow a fault detection criterion 930 of a maximum voltage V_{DS} across the power device.

The gate driver 925 also includes a control circuit 925D configured to generate gate signals Vₒ 925F to drive the gate G of the power device 924. The gate driver 925 also includes an input configured to receive a switching signal 906, such as a PWM signal for switching the power device. The switching signal 906 can be used to turn on the current source I_{driver} 925A, either directly or through the control circuit 925D. The gate driver 925 also includes other inputs such as a power input Vcc and a ground input connected to the source S of the power device.

The off-the-shelf current source I_{driver} 925A can be inadequate in providing the fast overcurrent detection response that is required from a SiC MOSFET. Thus, an additional current source I_{add} 926 is included in the protection circuit, which can supply current I_{charge} 927B to the capacitor to increase the speed at which the blanking capacitor C_{blank} 921 is charged. Using a constant current source I_{add} 926, instead of other voltage dependent current such as a resistor coupled to Vcc, the charging current is voltage independent and therefore remains at a same charging rate even when the voltage at the capacitor C_{blank} 921 is close to Vcc. Further, the charging rate of the capacitor C_{blank} 921 is proportional to the additional current source, so a high capacitor value for the capacitor C_{blank} 921 can be used to improve noise immunity.

The additional current source I_{add} 926 can be coupled to capacitor through a one-way device such as a diode (not shown). The one-way device can decouple the additional current source so that the additional current source is decoupled during operation of the protection circuit components of the capacitor 921, the resistor 922, and the diode 923. The constant charging current together with the decoupling of the additional current source can provide a fast response 931 in addition to a precision in the control of the overcurrent protection.

In the desaturation circuit model, the power device, such as a SiC MOSFET power device 924, is represented by a parasitic inductance L_{DS} connected to an internal resistance R_{DS}, and an ideal switch. The inductance L_{DS} can allow a modeling of a transient response 932, which is to ensure that the overcurrent fault detection includes the transient response of the power device corresponded to the fast switching of the power device.

There is a current I_{DS} 924A through the power device, and a voltage V_{DS} 924B across the power device. The current I_{DS} 924A can allow a modeling of a maximum current Iₘₐₓ, which is to ensure that the overcurrent fault detection includes a constraint of a maximum current that the power device can accept before being turned off due to overcurrent. The voltage V_{DS} 924B can allow a modeling of a maximum voltage Vₘₐₓ, which can be provided to the monitor circuit 925B as the voltage Vₘₒₙᵢₜₒᵣ 925E, which is to ensure that the overcurrent fault detection includes a constraint of a maximum voltage across the power device.

By using the parasitic inductance L_{DS} in the calculation of the components of the desaturation circuit, the overcurrent fault detection can have high noise immunity, at least against the fast switching speed of the power device with no false triggering. With the components of the desaturation circuit including an additional current source, the fast blanking time requirement for SIC MOSFET can be automatically satisfied due to the fast charging of the blanking capacitor using the calculated additional current source.

FIG. 4B shows a circuit model for the desaturation circuit, without components of the gate driver that do not contribute to the circuit model. The current sources I_{driver} 925A and I_{add} 926 are combined to form a total current source Iₜₒₜₐₗ 927. A portion I_{Cblank} 927C of the total current source Iₜₒₜₐₗ 927 flows to charge the capacitor C_{blank} 921. A portion Iₜₒₜₐₗ-I_{Cblank} 927D of the total current source Iₜₒₜₐₗ 927 flows to a branch including the resistor 922 and the diode 923, and then merges with the current I_{DS} 924A of the power device to flow through the inductance L_{DS} and the resistor R_{DS}.

The monitor circuit 925B is decoupled from the circuit model due to the high input impedance of the monitor circuit. The control circuit 925D is also decoupled from the circuit model.

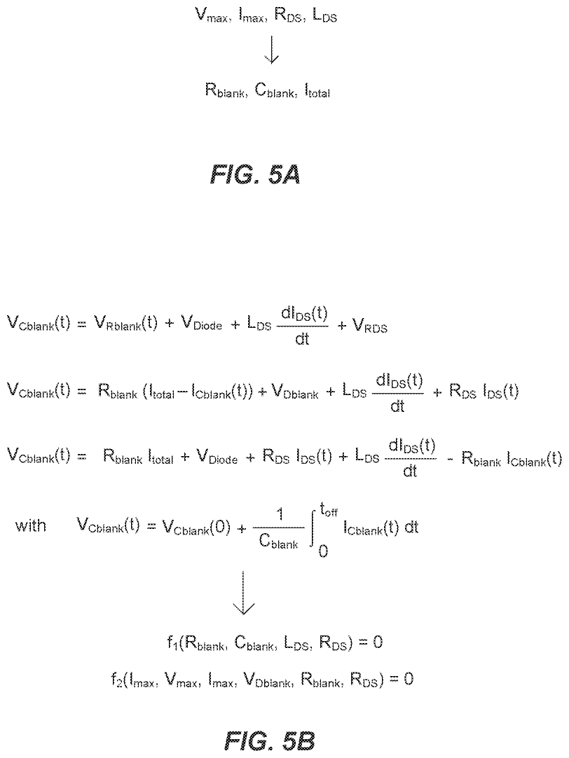

FIGS. 5A-5B illustrate algorithm schematics for determining components of a protection circuit according to some embodiments. FIG. 5A shows a concept of an algorithm, using constraints of a maximum current through the power device and a maximum voltage of the power device to trigger a fault event. The algorithm uses a protection circuit model with specific parameters of the power device, such as source-drain resistance R_{DS} and inductance L_{DS}. One or more relationships of the values of the components of the protection circuit can be determined from the algorithm, such as the values of the blanking capacitor C_{blank}, the blanking resistor R_{blank}, and the total current source Iₜₒₜₐₗ.

FIG. 5B shows algorithm steps of the protection circuit model, which can be used to determine relationships between components of the protection circuit and the parameters causing the desaturation trigger event. From the circuit model, the voltage V_{Cblank} across the blanking capacitor C_{blank} is the same as the sum of the voltages across the diode Diode, the blanking resistor R_{blank}, the parasitic inductance Los, and the internal resistor R_{DS} of the power device. With the current through the blanking resistor R_{blank} being the difference between the total current source Iₜₒₜₐₗ and the current through the blanking capacitor C_{blank}, the voltage drop across the blanking resistor R_{blank} is R×(Iₜₒₜₐₗ−I_{Cblank}(t)). The total current through the power device, e.g., through the parasitic inductance L_{DS}, and the internal resistor R_{DS} of the power device, is the sum of the current through the blanking resistor R_{blank} and the current I_{DS} of the power device. Since the current through the blanking resistor R_{blank} is much smaller than the current I_{DS} of the power device, the total current through the power device can be approximate as the current I_{DS}.

As such, the voltage loop around the circuit model is

$${V}_{Cblank} ( t ) = {V}_{diode} + {R}_{blank} \times ( {I}_{total} - {I}_{Cblank} ( t ) ) + {R}_{DS} \times {I}_{DS} ( t ) + {L}_{DS} \times \frac{{dI}_{DS} ( t )}{dt} \qquad ( 1 )$$

In the above equation, R_{blank} is the blanking resistor and C_{blank} is the blanking capacitor. V_{Cblank} (t) is the voltage across the blank capacitor C_{blank} as a function of time.

V_{diode} is the voltage drop across the diode. There can be multiple diodes to reduce the parasitic capacitance in the connection between the source of the MOSFET and the measurement circuit at the junction of the blanking resistor and capacitor.

Iₜₒₜₐₗ is the total external current provided to the blanking resistor and capacitor. The total current Iₜₒₜₐₗ includes a current source I_{driver} provided by the gate driver circuit 925 and an additional current source I_{add}, which is added to increase the rate of charge of the blanking capacitor, e.g., to reduce the response time of the gate driver circuit when an overcurrent fault is detected.

R_{DS} and L_{DS} are the internal ON resistance and the parasitic inductance of the MOSFET, respectively. Value of R_{DS} and Los can be found in the datasheet of the MOSFET, or by performing measurements on the MOSFET. L_{DS}×dI_{DS}(t)/dt is the voltage drop across the MOSFET when the MOSFET switches state.

Equation (1) can be separated into different equations based on static and dynamic conditions

$${V}_{Cblank} ( t ) = {V}_{diode} + {R}_{blank} \times {I}_{total} + {R}_{DS} \times {I}_{DS} ( t ) \qquad ( 2 )$$

$${R}_{blank} \times {I}_{Cblank} ( t ) = {L}_{DS} \times \frac{{dI}_{DS} ( t )}{dt} \qquad ( 3 )$$

For boundary conditions, at time t=0, I_{DS} (0)=0, V_{Cblank} (0)=0, and I_{Cblank} (0)=0. Further, at time t=0, the current I_{DS} cannot change instantaneously, so dI_{DS}(t=0)/dt=0.

$${V}_{Cblank} ( 0 ) = {V}_{diode} + {R}_{blank} \times {I}_{total} \qquad ( 4 )$$

At t=t_{off}, which is the time that the overcurrent fault is detected,

$${V}_{Cblank} ( {t}_{off} ) = {V}_{th} \qquad ( 5 )$$

$${I}_{DS} ( {t}_{off} ) = {I}_{max} \qquad ( 6 )$$

The above equations can be solved to provide relationships between the components of the protection circuit.

$${R}_{blank} \times {C}_{blank} = {L}_{DS} / {R}_{DS} \qquad ( 7 )$$

$${R}_{blank} \times {I}_{total} = {V}_{max} - {V}_{diode} - {R}_{ds} \times {I}_{max} \qquad ( 8 )$$

The equations and calculations above use an initial condition at the switching time of the power device as a boundary condition. Other boundary conditions can be used, such as an initial condition when the protection circuit is at steady state, such as after the voltage Vₘₒₙᵢₜₒᵣ at the blanking capacitor reaches a stable value when the current through the power device is steady. The induced voltage at the power device at the onset of the overcurrent fault from the steady state Vₘₒₙᵢₜₒᵣ can be much lower as compared to that at the switching time of the PWM switching signal, so the power device can also be protected against overcurrent faults occurring at steady state times.

As can be seen, the product of the blanking resistor with the blanking capacitor is related to the parameters of the power device, e.g., to a ratio of the inductance on the resistance of the power device. Thus, to have an effective low pass filter, the blanking capacitor and resistor are selected as a function of the parameters of the power device. The value of the blanking capacitor can be selected to be large, such as above 100 pF, above 200 pF, such as 220 pF, or even higher, such as above 470 pF or 1000 pF.

To adequately protect the power device, especially in high switching applications, the total current source in the protection circuit is selected based on the values of the desired maximum current through the power device and also to the desired maximum voltage across the power device. The value of the total current source can be higher than the preset current source used in a gate driver IC for Si IGBT. An additional external current source can be added to provide an adequate protection current source if a gate driver IC for Si IGBT is used.

Note that the above equation setting and calculations serve as an attempt at explaining the methodology for determining the values of the components in the protection circuit using circuit models with desired constraints and limitations. There can be flaws, deficiencies, inaccuracies or miscalculation in the equations and calculations, which are not meant to limit or restrict the scope of the invention. The scope of the invention should, therefore, be determined with reference to the appended claims along with the scope of equivalents to which such claims are entitled.

The desaturation protection circuit can protect the power devices by limiting the current through the power devices, in addition to a maximum voltage across the power device for a voltage allowance for disturbances to avoid unwanted tripping. Further, with proper selections of the circuit components, such as the current source, the blanking capacitor and resistor, and with the consideration of the parasitic inductance of the power devices, the protection circuit can be made independent of current gradient, e.g., independent of the fast switching of SiC MOSFETs, and is just dependent on the flowing current. Further, the parameters of each power device in the power module are characterized in the evaluation of the protection circuit, which can provide overcurrent fault detection for high speed switching of the power devices.

As shown, the protection circuit is based on the form of a desaturation circuit with an added current source, and with the component values determined based on a circuit model using at least the parasitic inductance of the power device. Other short circuit protection circuits can be used, such as a shunt protection circuit or a senseFET current protection circuit.

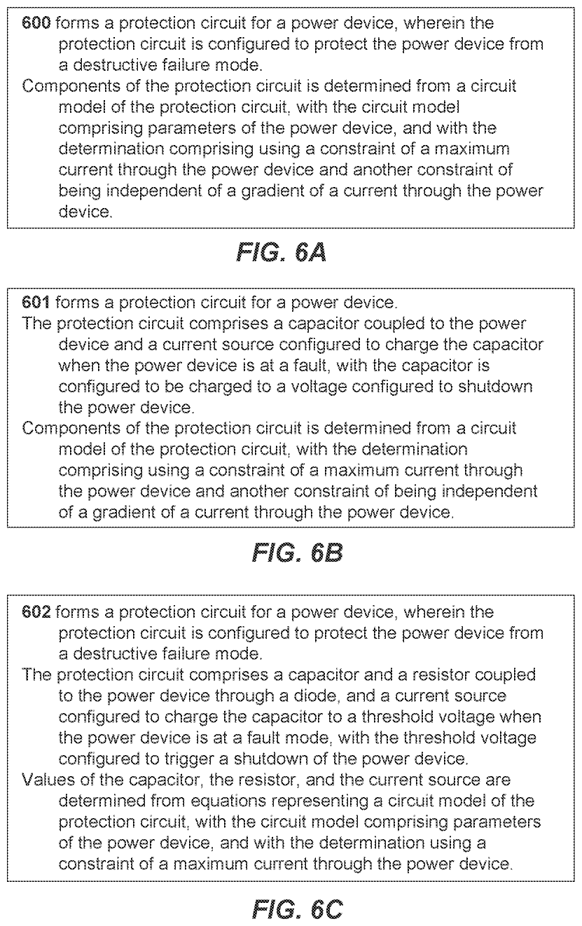

FIG. 6A-6C illustrate flow charts for forming a protection circuit for a power device according to some embodiments. FIG. 6A shows a protection circuit with components calculated from a circuit model of the protection circuit, with the circuit model including parameters of the power device such as a parasitic inductance for providing a voltage surge due to fast switching, and an internal resistance for providing a voltage drop across the power device. The calculations are based on one or more constraints, such as a constraint of a predetermined maximum current through the power device, a constraint of a predetermined maximum voltage across the power device, or a constraint of being independent of current gradients through the power device during power switching.

Operation 600 forms a protection circuit for a power device, with the protection circuit configured to protect the power device from a destructive failure mode such as a short circuit fault. Values of components in the protection circuit is determined from a circuit model of the protection circuit, with the circuit model comprising parameters of the power device, and with the determination comprising using a constraint of a maximum current through the power device and another constraint of being independent of a gradient of a current through the power device. Other constraint can be included, such as a maximum voltage across the power device.

FIG. 6B shows a desaturation protection circuit for a power device including a current source configured to charge a capacitor, with the voltage across the capacitor is monitored to provide an indication of an overcurrent fault event in the power device. The protection circuit can have other components, in addition to the current source and the capacitor, such as a resistor to limit the current flow, and one or more diodes to decouple the power device from the protection circuit during an overcurrent fault event.

Values of the components of the protection circuit are calculated from a circuit model of the protection circuit, with the circuit model including parameters of the power device such as a parasitic inductance for providing a voltage surge due to fast switching, and an internal resistance for providing a voltage drop across the power device. The calculations are based on one or more constraints, such as a constraint of a predetermined maximum current through the power device, a constraint of a predetermined maximum voltage across the power device, or a constraint of being independent of current gradients through the power device during power switching.

Operation 601 forms a protection circuit for a power device. The protection circuit includes a capacitor coupled to the power device and a current source configured to charge the capacitor when the power device is at a fault, with the capacitor is configured to be charged to a threshold voltage configured to shutdown the power device.

Values of components in the protection circuit is determined from a circuit model of the protection circuit, with the circuit model comprising parameters of the power device, and with the determination comprising using a constraint of a maximum current through the power device and another constraint of being independent of a gradient of a current through the power device. Other constraint can be included, such as a maximum voltage across the power device.

FIG. 6C shows a desaturation protection circuit of a current source configured to charge a capacitor, with values of the components of the desaturation protection circuit determined from a constraint of a predetermined maximum current through the power device.

Operation 602 forms a protection circuit for a power device configured to protect the power device from a destructive failure mode. The protection circuit comprises a capacitor and a resistor coupled to the power device through a diode, and a current source configured to charge the capacitor to a threshold voltage when the power device is at a fault mode, with the threshold voltage configured to trigger a shutdown of the power device.

Values of the capacitor, the resistor, and the current source are determined from equations representing a circuit model of the protection circuit, with the circuit model comprising parameters of the power device, and with the determination using a constraint of a maximum current through the power device.

Configurations of the protection circuit based on different gate driver circuits.

In some embodiments, the desaturation protection circuit can be configured to use with a gate driver circuit designed for Si IGBT, e.g., a gate driver circuit having a fixed internal current source. Alternatively, the desaturation protection circuit can be configured to use a gate driver circuit having no internal current source, or a gate driver circuit having a variable internal current source, e.g., an internal current source having the current value adjustable to suit the power device used in a power switching module.

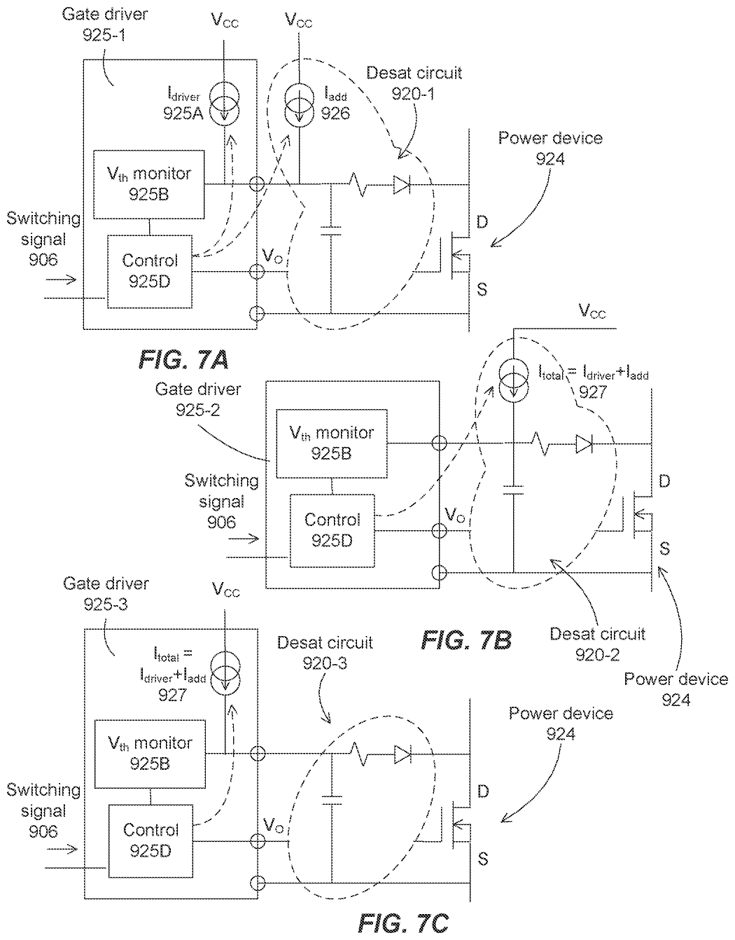

FIGS. 7A-7C illustrate configurations of a protection circuit according to some embodiments. FIG. 7A shows a protection circuit 920-1 configured to work with a gate driver circuit 925-1 that has a fixed internal current source I_{driver} 925A. For example, Si IGBT power devices can be adequately protected by a desaturation circuit using a small range of current source values. Thus, gate driver circuits for Si IGBT can be formed in an integrated circuit package, including a monitor circuit 925B and a control circuit 925D, to form gate driver ICs that can be used in desaturation circuit for Si IGBT protection. To simplify the protection circuit design, the gate driver IC 925-1 can be incorporated with an internal current source I_{driver} 925A, since the current source I_{driver} 925A requires a control signal provided by the switching signal 906 available in the gate driver circuit.

The value of the internal current source I_{driver} 925A in a gate driver IC 925-1 can be inadequate to provide fast responses in cases of overcurrent fault events for SiC MOSFET power devices 924. Thus, a protection circuit can include an additional current source I_{add} 926, which is external to the gate driver IC 925-1. The value of the additional current source I_{add} 926 can be determined from a total current source value Iₜₒₜₐₗ required to operate the protection circuit, as calculated above based on a maximum current and voltage across the power device, together with other parameters of the power device, e.g. I_{add}=Iₜₒₜₐₗ-I_{driver}. Further, the additional current source I_{add} 926 is driven by a control signal, either provided directly by the switching signal 906 or through the control circuit 925D.

FIG. 7B shows a protection circuit 920-2 configured to work with a gate driver circuit 925-2 that does not have an internal current source. The gate driver circuit can have a monitor circuit 925B configured to monitor a voltage related to the power device 924, and a control circuit 925D to generate gate signals to drive or to shut down the power device.

The protection circuit can include a total current source Iₜₒₜₐₗ 927, which is determined from a total current source value Iₜₒₜₐₗ required to operate the protection circuit, as calculated above based on a maximum current and voltage across the power device, together with other parameters of the power device, e.g. Iₜₒₜₐₗ=I_{driver}.+I_{add}. The total current source Iₜₒₜₐₗ 927 is driven by a control signal, either provided directly by the switching signal 906 or through the control circuit 925D.

FIG. 7C shows a protection circuit 920-3 configured to work with a gate driver circuit 925-3 that has an adjustable internal current source. The gate driver circuits 925-3 can be a version of a gate driver circuit 925-1 for Si IGBT, with a difference being having an adjustable current source Iₜₒₜₐₗ 927 instead of a fixed current source I_{driver} 925A. And similar to the gate driver circuit 925-1, the adjustable current source Iₜₒₜₐₗ 927 is controlled by a control signal provided by the switching signal 906 through the control circuit 925D.

The value of the internal total current source Iₜₒₜₐₗ 927 can be determined from a total current source value Iₜₒₜₐₗ required to operate the protection circuit, as calculated above based on a maximum current and voltage across the power device, together with other parameters of the power device.

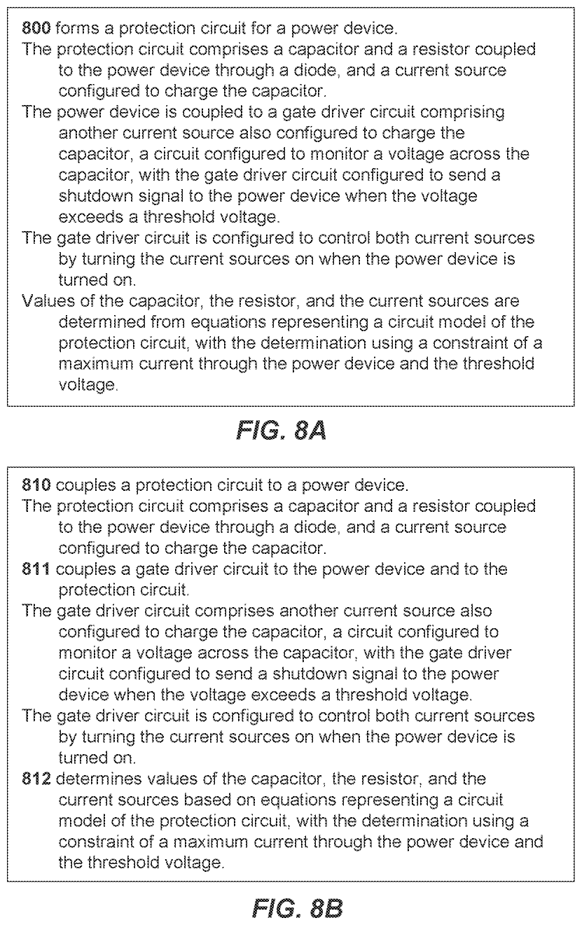

FIGS. 8A-8B illustrate flow charts for forming a protection circuit having a current source, with the protection circuit configured to work with a gate driver circuit already having another current source according to some embodiments. FIG. 8A shows a flow chart for forming a protection circuit for a power device. Operation 800 forms a protection circuit for a power device. The protection circuit comprises a capacitor and a resistor coupled to the power device through a diode, and a first current source configured to charge the capacitor.

The power device is coupled to a gate driver circuit comprising a second current source also configured to charge the capacitor, a circuit configured to monitor a voltage across the capacitor, with the gate driver circuit configured to send a shutdown signal to the power device when the voltage exceeds a threshold voltage.

The gate driver circuit is configured to control the first and second current sources by turning on the first and second current sources when the power device is turned on.

Values of the capacitor, the resistor, and a total current source are determined from equations representing a circuit model of the protection circuit, with the determination using a constraint of a maximum current through the power device and the threshold voltage, and with the first current source being a difference between the total current source and the second current source.

FIG. 8B shows a method for forming a protection circuit for a power device. Operation 810 couples a protection circuit to a power device. The protection circuit comprises a capacitor and a resistor coupled to the power device through a diode, and a first current source configured to charge the capacitor.

Operation 811 couples a gate driver circuit to the power device and to the protection circuit. The gate driver circuit comprises a second current source also configured to charge the capacitor, a circuit configured to monitor a voltage across the capacitor, with the gate driver circuit configured to send a shutdown signal to the power device when the voltage exceeds a threshold voltage.

The gate driver circuit is configured to control the first and second current sources by turning on the first and second current sources when the power device is turned on.

Operation 812 determines values of the capacitor, the resistor, and a total current source based on equations representing a circuit model of the protection circuit, with the determination using a constraint of a maximum current through the power device and the threshold voltage, and with the first current source being a difference between the total current source and the second current source.

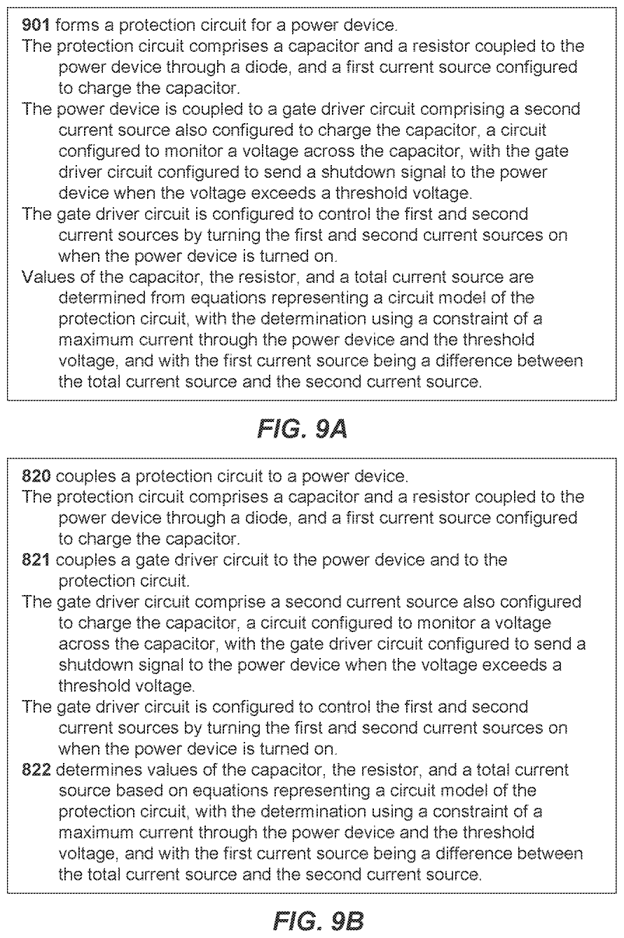

FIGS. 9A-9B illustrate flow charts for forming a protection circuit having a current source, with the protection circuit configured to work with a gate driver circuit not having a current source according to some embodiments. FIG. 9A shows a flow chart for forming a protection circuit for a power device. Operation 801 forms a protection circuit for a power device. The protection circuit comprises a capacitor and a resistor coupled to the power device through a diode, and a current source configured to charge the capacitor.

The power device is coupled to a gate driver circuit comprising a circuit configured to monitor a voltage across the capacitor, with the gate driver circuit configured to send a shutdown signal to the power device when the monitored voltage exceeds a threshold voltage. There is no current source in the gate driver circuit.

The gate driver circuit is configured to control the current source by turning on the current source when the power device is turned on.

Values of the capacitor, the resistor, and the current source are determined from equations representing a circuit model of the protection circuit, with the determination using a constraint of a maximum current through the power device and the threshold voltage.

FIG. 9B shows a method for forming a protection circuit for a power device. Operation 820 couples a protection circuit to a power device. The protection circuit comprises a capacitor and a resistor coupled to the power device through a diode, and a current source configured to charge the capacitor.

Operation 821 couples a gate driver circuit to the power device and to the protection circuit. The gate driver circuit comprises a circuit configured to monitor a voltage across the capacitor, with the gate driver circuit configured to send a shutdown signal to the power device when the voltage exceeds a threshold voltage. There is no current source in the gate driver circuit.

The gate driver circuit is configured to control the current source by turning on the current source when the power device is turned on.

Operation 822 determines values of the capacitor, the resistor, and the current source based on equations representing a circuit model of the protection circuit, with the determination using a constraint of a maximum current through the power device and the threshold voltage.

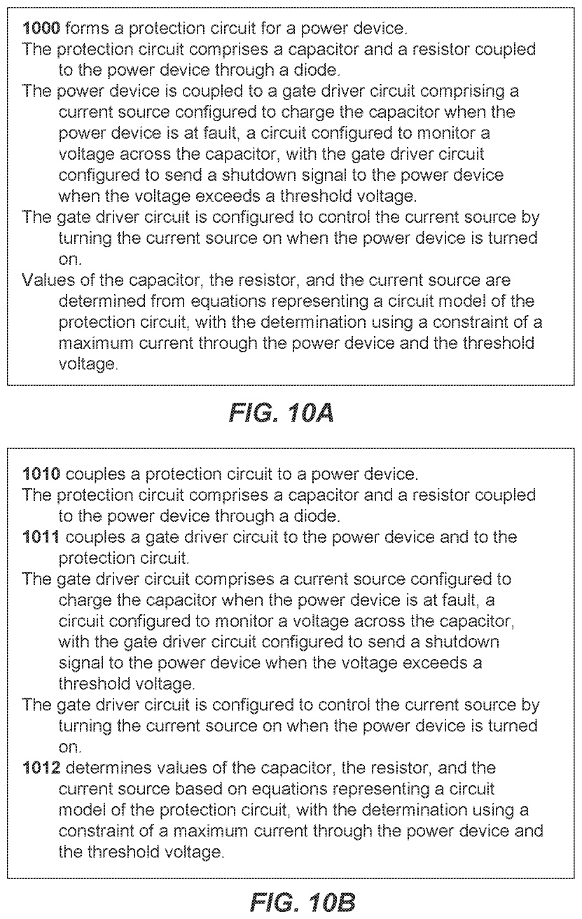

FIGS. 10A-10B illustrate flow charts for forming a protection circuit not having any current source, with the protection circuit configured to work with a gate driver circuit having a current source according to some embodiments. FIG. 10A shows a flow chart for forming a protection circuit for a power device. Operation 1000 forms a protection circuit for a power device. The protection circuit comprises a capacitor and a resistor coupled to the power device through a diode.

The power device is coupled to a gate driver circuit comprising a current source configured to charge the capacitor when the power device is at fault, a circuit configured to monitor a voltage across the capacitor, with the gate driver circuit configured to send a shutdown signal to the power device when the voltage exceeds a threshold voltage.

The gate driver circuit is configured to control the current source by turning the current source on when the power device is turned on.

Values of the capacitor, the resistor, and the current source are determined from equations representing a circuit model of the protection circuit, with the determination using a constraint of a maximum current through the power device and the threshold voltage.

FIG. 10B shows a method for forming a protection circuit for a power device. Operation 1010 couples a protection circuit to a power device. The protection circuit comprises a capacitor and a resistor coupled to the power device through a diode.

Operation 1011 couples a gate driver circuit to the power device and to the protection circuit. The gate driver circuit comprises a current source configured to charge the capacitor when the power device is at fault, a circuit configured to monitor a voltage across the capacitor, with the gate driver circuit configured to send a shutdown signal to the power device when the voltage exceeds a threshold voltage.

The gate driver circuit is configured to control the current source by turning the current source on when the power device is turned on.

Operation 1012 determines values of the capacitor, the resistor, and the current source based on equations representing a circuit model of the protection circuit, with the determination using a constraint of a maximum current through the power device and the threshold voltage.

### Mirror Configuration For Current Source

In some embodiments, the current source can be configured as a current mirror, which serves as a simple current regulator, supplying nearly constant current to a load over a wide range of load resistances. The regulated current through the current mirror configuration can be adjusted by adjusting the resistors in the current mirror configuration. A one-way element, such as a diode, can be added to the output of the current mirror configuration, to decouple the current mirror from the load.

The current mirror configuration can provide a low cost and simple current source to generate enough extra current to linearly charge the blanking capacitor independently of the gate driver I_{C}.

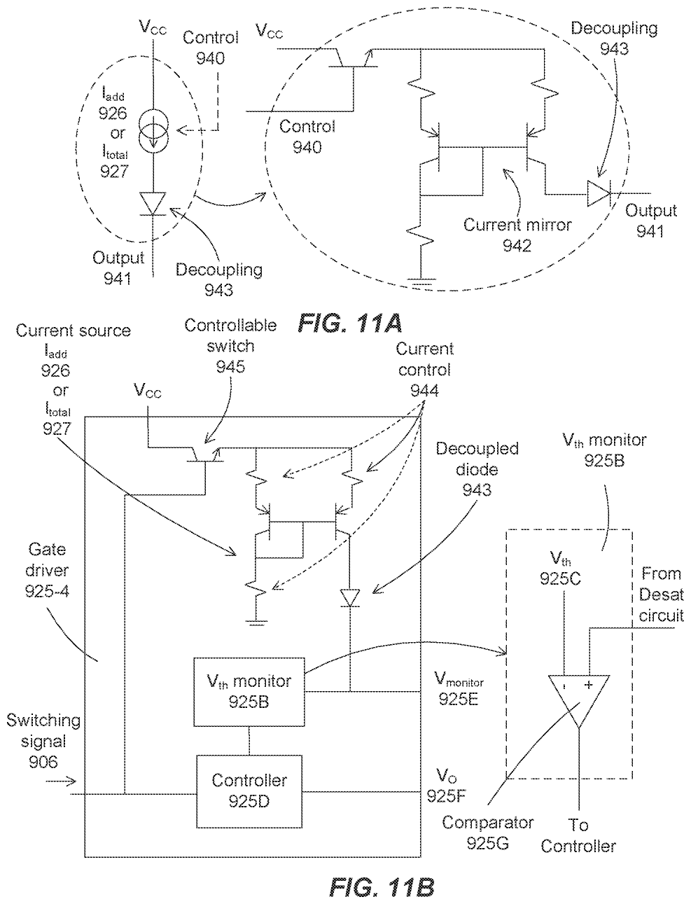

FIGS. 11A-11B illustrate a mirror configuration for a current source in a protection circuit according to some embodiments. FIG. 11A shows a current mirror configuration 942 for a current source I_{add} 926 or Iₜₒₜₐₗ 927, together with a decoupling diode 943 for isolating the current source from the protection circuit. The current source includes a controllable switch 945, controlled by a control signal 940, such as the switching signal 906. The current source has an output 941, which is coupled to a blanking capacitor for charging the capacitor. The current source can be a total current source Iₜₒₜₐₗ 927, for example, in the case that a gate driver does not have a current source, or in the case that a gate driver has an adjustable current source. The current source can be an additional current source I_{add} 926, for example, in the case that a gate driver has an internal current source I_{driver}. The current mirror configuration can include one or more resistors, which are configured to adjust the current generated by the current source. The resistors can also be configured to increase an output impedance of the current source.

FIG. 11B shows a gate driver circuit 925-4 using a current mirror configuration for a current source, which can be coupled with a protection circuit for a power device. The gate driver circuit 925-4 includes an adjustable current source, which can be adjusted to form current source I_{add} 926 or Iₜₒₜₐₗ 927. For example, one or more resistors 944 of the current mirror configuration can be provided as external elements, and thus the value of the current source can be adjusted to fit with the protection circuit designed for a power device. The current source can be controlled by a controllable switch 945, with a control signal such as the switching signal 906. The output of the current source can be coupled to a diode 943, to allow the current source to be decoupled from the protection circuit that the gate driver circuit is connected to.

The gate driver circuit can include other circuits, such as a monitor circuit 925B, which can include a comparator 925G that can compare the monitor voltage Vₘₒₙᵢₜₒᵣ 925E to a threshold voltage 925E. The gate driver circuit can include a control circuit 925D, which is configured to generate a gate voltage 925F to drive the power device, such as to turn on or off the power device.

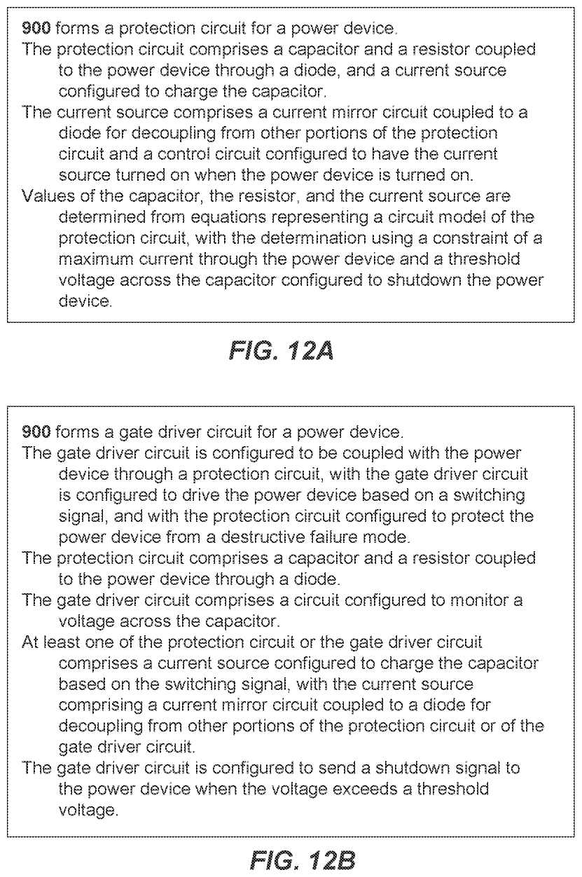

FIGS. 12A-12B illustrate flow charts for forming a protection circuit having a mirror configuration current source according to some embodiments. FIG. 12A shows a flow chart for forming a protection circuit having a mirror configuration current source for a power device. Operation 1200 forms a protection circuit for a power device. The protection circuit comprises a capacitor and a resistor coupled to the power device through a diode, and a current source configured to charge the capacitor.

The current source comprises a current mirror circuit coupled to a diode for decoupling from other portions of the protection circuit and a control circuit configured to have the current source turned on when the power device is turned on.

Values of the capacitor, the resistor, and the current source are determined from equations representing a circuit model of the protection circuit, with the determination using a constraint of a maximum current through the power device and a threshold voltage across the capacitor configured to shutdown the power device.

FIG. 12B shows a flow chart for forming a gate driver circuit for a power device, which is coupled to a protection circuit. Operation 1201 forms a gate driver circuit for a power device. The gate driver circuit is configured to be coupled with the power device through a protection circuit, with the gate driver circuit is configured to drive the power device based on a switching signal, and with the protection circuit configured to protect the power device from a destructive failure mode.

The protection circuit comprises a capacitor and a resistor coupled to the power device through a diode. The gate driver circuit comprises a circuit configured to monitor a voltage across the capacitor.

At least one of the protection circuit or the gate driver circuit comprises a current source configured to charge the capacitor based on the switching signal, with the current source comprising a current mirror circuit coupled to a diode for decoupling from other portions of the protection circuit or of the gate driver circuit.

The gate driver circuit is configured to send a shutdown signal to the power device when the voltage exceeds a threshold voltage.

### Precharged Circuit For Blanking Capacitor

In some embodiments, the protection circuit further includes a precharged circuit configured to set the monitored voltage at a base voltage close to the threshold voltage, e.g., close to the voltage at which the short-circuit fault detection is activated. For example, the precharged circuit is configured to set the monitored voltage at a new base voltage, e.g., at a higher voltage closer to the threshold voltage, as compared to an old base voltage used in protecting Si IGBT power devices. In addition to an additional current source, which is configured to increase the charging speed of the blanking capacitor, the new base voltage can further improve the fault detection responses with a smaller gap in voltage.

In some embodiments, the precharged circuit can be an adjustable precharged circuit, e.g., the value of the precharged circuit can be adjusted and set at the time of design, based on the requirements of the power device for fast overcurrent detection, in consideration of the need for avoiding false trigger. For example, the precharged circuit can be configured to provide a tolerance level, e.g., the difference between the threshold voltage and the base voltage, at different values, such as at less than 5 V, less than 4 V, less than 3 V, less than 2 V, or less than 1 V, depending on the power device module.

The precharged circuit is coupled to the protection circuit using a one-way circuit, such as a diode. The one-way circuit is configured to set the base voltage at a desired level, and is decoupled from the protection circuit when the monitored voltage increases. With the one-way circuit, the precharged circuit can provide an adjustable base voltage while not interfering with the protection operation of the protection circuit.

In some embodiments, the precharged circuit can include a voltage source, such as a Zener based voltage source, coupled to a diode. A low resistor is coupled to the Zener diode to allow a fast voltage response to the Zener voltage, for example, from an off state.

The protection circuit with the precharged circuit can be configured to increase the speed of the detection of overcurrent faults, while still provide a voltage allowance for disturbances to avoid unwanted protection tripping. Thus, the protection circuit can provide a reliable protection of power devices, including SiC MOSFETs and Si IGBTs.

The high base voltage level, e.g., the lower tolerance level of the fault voltage criterion is well suited to a protection circuit providing an overcurrent fault detection based on programmable overcurrent threshold, such as an overcurrent fault based on a predetermined maximum current and voltage through the power device, and based on a protection circuit design that offers protection independent of current gradient. The protection circuit thus can protect the power devices in case of a high speed switching configuration, but also to protect other components with a soft desaturation behavior such as power inductors or transformers.

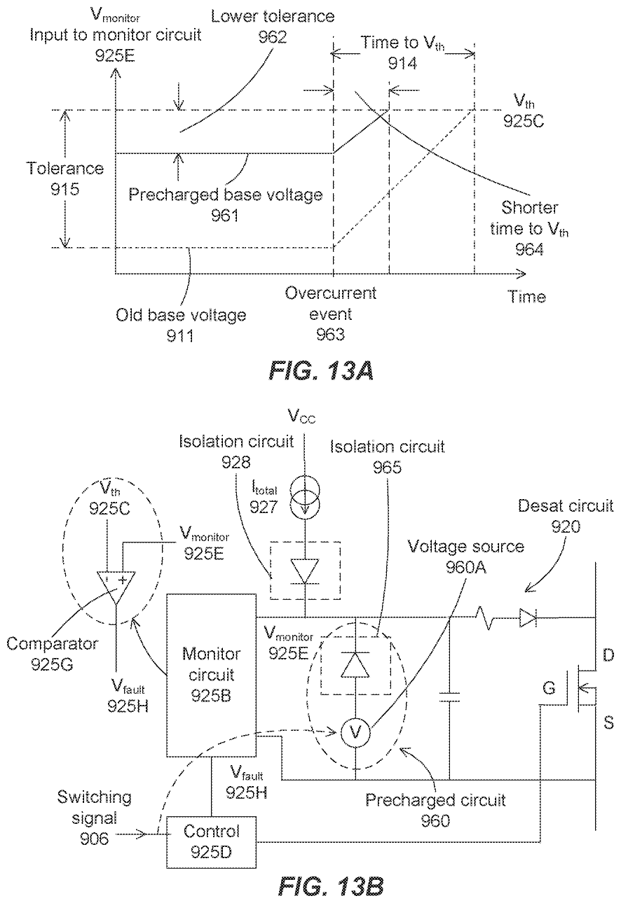

FIGS. 13A-13B illustrate a protection circuit having a precharged circuit according to some embodiments. FIG. 13A shows a timing diagram for a protection circuit with and without a precharged circuit. Without the precharged circuit, the monitor voltage Vₘₒₙᵢₜₒᵣ 925E at the blanking capacitor which is inputted to the monitor circuit is at an old base voltage level 911, which is defined by the components of the protection circuit, such as by the voltage drop across the blanking resistor, the voltage across the one or more diodes, and the voltage across the power device during saturation. A typical value for the old base voltage is about 1-3 V.

At the onset of an overcurrent event 963, the voltage at the blanking capacitor increases due to the reverse bias of the diode that decouples the capacitor from the power device. When the capacitor voltage reaches a threshold voltage Vₜₕ 925C of about 7-9V, in a blanking time 914 of about 1-3 microseconds, the overcurrent fault condition is triggered to shut down the power device. The difference between the threshold voltage and the old base voltage is the tolerance level 915, about 4-8 V, is large to accommodate noise spikes in the protection circuit. The blanking time of a few microseconds is adequate for Si IGBT, but can be too long for fast switching SiC MOSFET power devices.

A precharged circuit can be added to the protection circuit to increase the base voltage, for example, to increase the base voltage from an old base voltage 911 to a precharged base voltage 961. For example, the precharged base voltage can be about 5-8 V, which is configured to provide a lower tolerance level 962, which is about 1-3 V, or 2-3V. With the higher precharged base voltage 961, the response time 964, e.g., the time from the precharged base voltage 961 to the threshold voltage 925C, is much shorter. The precharged base voltage, in addition to the charging rate of the blanking capacitor, can be designed so that the response time 964 is suitable for the power device, such as for the fast switching SIC MOSFETs.

FIG. 13B shows a schematic of a protection circuit 920 having a precharged circuit 960 to provide a fast fault detection while still maintaining a high noise immunity. The precharged circuit 960 can be coupled to the protection circuit using a one-way component, such as a diode, to raise a base voltage, e.g., the voltage of the blanking capacitor during normal operating conditions, to be closer to a threshold voltage, e.g., the voltage configured to trigger the desaturation protection to shut down the power device. Since the precharged circuit is decoupled from the protection circuit during the fault condition, the precharged circuit does not affect the protection scheme of the power device. Thus, the determination of the components of the protection circuit, such as the value of the blanking capacitor is not affected by the presence of the precharged circuit. A high value blanking capacitor can be selected, such as between 100 pF and 1000 pF, such as in a vicinity of 220 pF, to eliminate noise spikes.

A benefit of the high value blanking capacitor can provide a low noise protection circuit, which can allow for the threshold voltage to be closer to a base voltage, which can provide faster overcurrent fault responses.

The protection circuit 920 includes a blanking capacitor, a blanking resistor. and one or more diodes for coupling with a power device. The protection circuit 920 also includes a current source Iₜₒₜₐₗ 927, configured to charge the blanking capacitor. An isolation circuit 928, such as a diode, is used for one-way isolating the current source from the capacitor. With the isolation diode 928, a simple current source design can be used, such as a current mirror configuration as discussed above. The protection circuit 920 also includes a monitor circuit 925B, which can include a comparator 925G for comparing a monitor voltage Vₘₒₙᵢₜₒᵣ 925E with a threshold voltage Vₜₕ 925C. The protection circuit 920 also includes a control circuit 925D, which is configured to send gate signals to the power device for turning on and off the power device. The control circuit 925D is also configured to send a turning off gate signal to the power device, such as a soft shut down signal, when receiving a fault voltage V_{fault} 925H from the comparator circuit, indicating that the monitor voltage Vₘₒₙᵢₜₒᵣ 925E reaches the threshold voltage Vₜₕ 925C.

A precharged circuit 960 can include a voltage source 960A and an isolation circuit 965. The precharged circuit can include only the voltage source 965, and is coupled to the blanking capacitor through an isolation circuit 965. The isolation circuit 965, such as a diode, is used for one-way isolating the precharged circuit 960 or the voltage source 960A from the capacitor. With the isolation diode 965, when the voltage across the capacitor drops below the precharged circuit, the precharged circuit is connected to the capacitor to bring the capacitor voltage up to the voltage level of the precharged circuit. When the voltage across the capacitor is higher than that of the precharged circuit, the precharged circuit is decoupled from the capacitor to allow the capacitor voltage to increase without any interference from the precharged circuit.

The one-way isolation current source Iₜₒₜₐₗ 927 and the one-way isolation precharged circuit 960 can allow a selection of the blanking resistor and capacitor with a much broader range, since the one-way isolation current source Iₜₒₜₐₗ 927 and the one-way isolation precharged circuit 960 do not affect the operation of the protection circuit. For example, the blanking capacitor can be chosen to be greater than 100 pF, 200 pF, 470 pF, or 1000 pF, while keeping a low RC constant, since the value of the blanking resistor can be chosen to satisfy the protection circuit model, after selecting the value for the blanking capacitor.

During normal operation, the voltage V_{DS} across the power device is low since the power device is in an ON state, and the diode is conductive. The current source Iₜₒₜₐₗ 927 flows to charge the capacitor, and also to the resistor, diode and through the power device. The capacitor voltage is thus a sum of the voltage drop across the resistor, the diode and the power device. If this capacitor voltage is lower than the voltage provided by the precharged circuit (plus the voltage across the isolation diode), the precharged circuit provides a current to the capacitor and resistor branches, to bring the capacitor voltage to the precharged base voltage 961, which is equal to the voltage of the precharged circuit (plus the isolation diode voltage).

When an overcurrent fault occurs, the voltage V_{DS} across the power device increases, which reverse bias the diode and blocks the flow of current through the blanking resistor branch. The current source then flows to the blanking capacitor, charging the capacitor to a higher voltage, e.g., higher than the precharged base voltage 961. The higher capacitor voltage reverse bias the isolation diode 965, and the precharged circuit 960 is decoupled from the protection circuit 920. When the capacitor voltage reaches the threshold voltage Vₜₕ 925G, an overcurrent fault is triggered, and a shut down gate signal is sent to the power device.

The difference between the precharged base voltage and the threshold voltage is a tolerance voltage for the protection circuit, e.g., the tolerance voltage is configured to account for noise spikes to avoid false triggering. The precharged circuit can customize the tolerance level, e.g., by adjusting the precharged base voltage, as a balance between fast triggering and noise spikes.

Since the protection circuit is designed for the specific power device by using the parameters of the power device, the tolerance margin due to different power devices is negligible. Further, since the protection circuit is designed to be independent of current gradient, e.g., independent of the transition voltage induced by the parasitic inductance, the tolerance margin due to fast switching transient is also negligible. As such, a low tolerance level, such as between 1 and 4 V, or between 2 and 3 V, for example, at around 2.5 V, can be used for the power device protection, including for SiC MOSFET power devices.

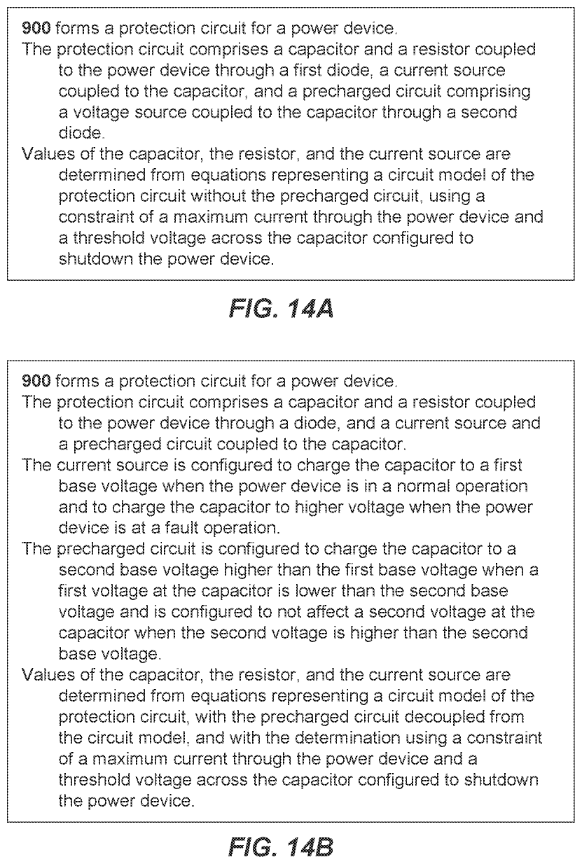

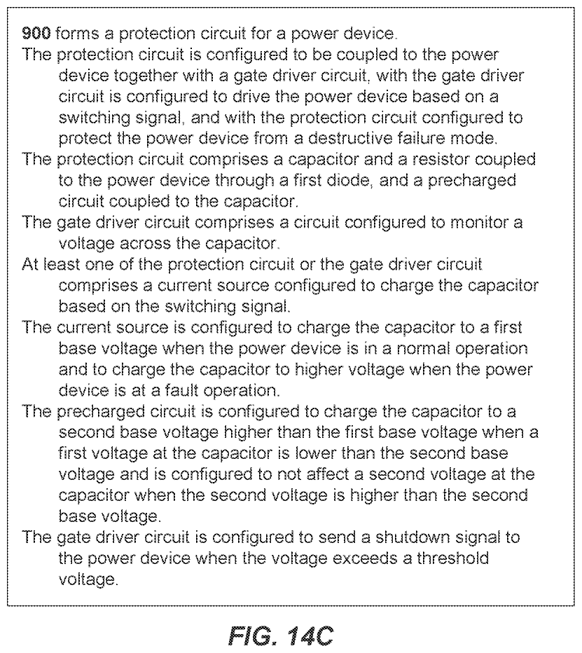

FIGS. 14A-14C show flow charts for forming a protection circuit having a precharged circuit according to some embodiments. FIG. 14A shows a flow chart for forming a protection circuit with a precharged circuit. Operation 1400 forms a protection circuit for a power device. The protection circuit comprises a capacitor and a resistor coupled to the power device through a first diode, a current source coupled to the capacitor, and a precharged circuit comprising a voltage source coupled to the capacitor through a second diode.

Values of the capacitor, the resistor, and the current source are determined from equations representing a circuit model of the protection circuit without the precharged circuit, using a constraint of a maximum current through the power device and a threshold voltage across the capacitor configured to shutdown the power device.

FIG. 14B shows a flow chart for forming a protection circuit with a precharged circuit configured to raise a base voltage for detection. Operation 1401 forms a protection circuit for a power device. The protection circuit comprises a capacitor and a resistor coupled to the power device through a diode, and a current source and a precharged circuit coupled to the capacitor.

The current source is configured to charge the capacitor to a first base voltage when the power device is in a normal operation and to charge the capacitor to higher voltage when the power device is at a fault operation.

The precharged circuit is configured to charge the capacitor to a second base voltage higher than the first base voltage when a first voltage at the capacitor is lower than the second base voltage and is configured to not affect a second voltage at the capacitor when the second voltage is higher than the second base voltage.

Values of the capacitor, the resistor, and the current source are determined from equations representing a circuit model of the protection circuit, with the precharged circuit decoupled from the circuit model, and with the determination using a constraint of a maximum current through the power device and a threshold voltage across the capacitor configured to shutdown the power device.

FIG. 14C shows a flow chart for forming a protection circuit having a precharged circuit, with the protection circuit coupled to a power device together with a gate driver circuit. Operation 1403 forms a protection circuit for a power device. The protection circuit is configured to be coupled to the power device together with a gate driver circuit, with the gate driver circuit is configured to drive the power device based on a switching signal, and with the protection circuit configured to protect the power device from a destructive failure mode.

The protection circuit comprises a capacitor and a resistor coupled to the power device through a first diode, and a precharged circuit coupled to the capacitor.

The gate driver circuit comprises a circuit configured to monitor a voltage across the capacitor.

At least one of the protection circuit or the gate driver circuit comprises a current source configured to charge the capacitor based on the switching signal.

The current source is configured to charge the capacitor to a first base voltage when the power device is in a normal operation and to charge the capacitor to higher voltage when the power device is at a fault operation.

The precharged circuit is configured to charge the capacitor to a second base voltage higher than the first base voltage when a first voltage at the capacitor is lower than the second base voltage and is configured to not affect a second voltage at the capacitor when the second voltage is higher than the second base voltage.

The gate driver circuit is configured to send a shutdown signal to the power device when the voltage exceeds a threshold voltage.

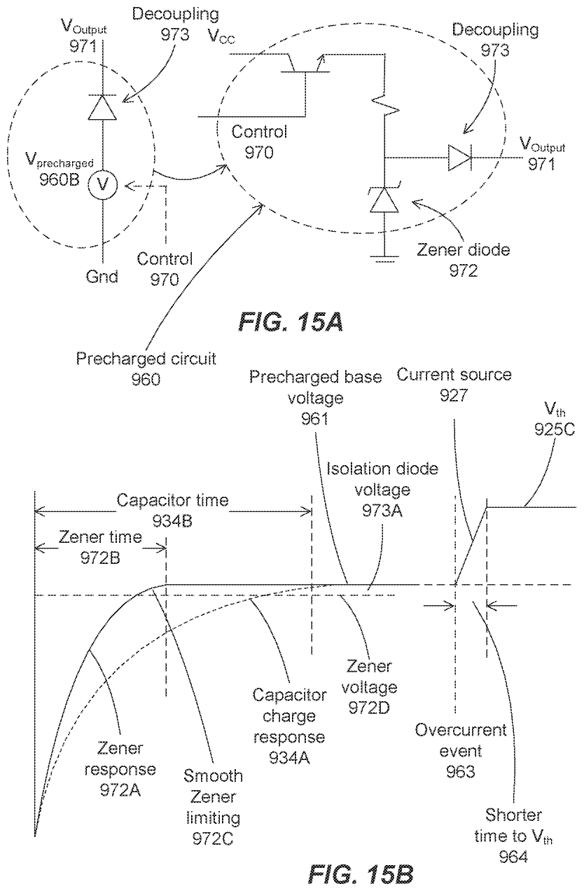

FIGS. 15A-15B illustrate a configuration of a precharged circuit according to some embodiments. The precharged circuit can include a voltage source coupled to an isolation circuit such as a diode. The voltage source is controlled by a switching signal, for example, to turn on the voltage source only when the power device is turned on.

FIG. 15A shows a schematic of a precharged circuit having a Zener diode based voltage source. The precharged circuit 960 includes a controllable voltage source configured to generate a voltage V_{precharged} 960B coupled to an isolation circuit including a decoupling diode 973. A control signal 970, such as a signal coming from a switching signal 906, can be used to turn on and off the precharged circuit, based on the status of the power device. The precharged circuit 960 is configured to provide an output voltage Vₒᵤₜₚᵤₜ 971 to the blanking capacitor when the power device is turned on. The output voltage Vₒᵤₜₚᵤₜ 971 is the sum of the precharged voltage V_{precharged} 960B and the voltage drop across the decoupling diode 973.

The precharged circuit can include a Zener based voltage source. A Zener diode 972 can be used to establish a constant voltage, e.g., the precharged voltage V_{precharged} 960B, by coupling with a power supply Vcc through a resistor to limit the current through the Zener diode. A semiconductor switch can be coupled to the precharged circuit to control the supply of Vcc to the Zener diode. The switch is controlled by a control signal 970, which is configured to turn on the precharged circuit when the power device is turned on. The precharged circuit is coupled to the blanking capacitor through a one-way isolation circuit, such as a diode. During normal operations, when the capacitor voltage is below the output voltage Vₒᵤₜₚᵤₜ 971, the decoupling diode is forward bias, and the precharged circuit is configured to raise the capacitor voltage to the output voltage Vₒᵤₜₚᵤₜ 971. During an overcurrent event, the capacitor voltage increases to be above the output voltage Vₒᵤₜₚᵤₜ 971, resulting in a reverse bias of the decoupling diode. The precharged circuit is decoupled from the capacitor due to the reverse bias decoupling diode.

The value of the Zener diode 972 determines the precharged voltage V_{precharged} 960B and the output voltage Vₒᵤₜₚᵤₜ 971. For example, the Zener diode can be selected to provide a tolerance level of between 2 and 4V, such as 3V, e.g., the Zener diode can have a voltage 2-4 V below the threshold voltage Vₜₕ that is used to trigger an overcurrent fault event.

The Zener based voltage source can provide a smooth voltage rise without overshoot. The voltage rise can also be fast by reducing the limiting resistor. The fast and smooth precharged voltage can provide high noise immunity for the protection circuit, especially for fast switching power device such as SiC or GaN MOSFETs.

FIG. 15B shows a timing diagram of a Zener diode precharged circuit during normal and fault operations. A Zener based voltage source can provide a response 972A with shorter time 972B and smoother rise 972C, as compared to, for example, a capacitor charge response 934A having longer time 934B. The precharged base voltage 961 includes the Zener voltage 972D and voltage 973A across the isolation or decoupling diode 973.

At an overcurrent event 963, the total current source 927 charges the capacitor to increase the capacitor voltage to the threshold voltage Vₜₕ 925C. Since the capacitor voltage only needs to increase from the precharged base voltage 961, the response can be fast due a short time 964 to Vₜₕ.

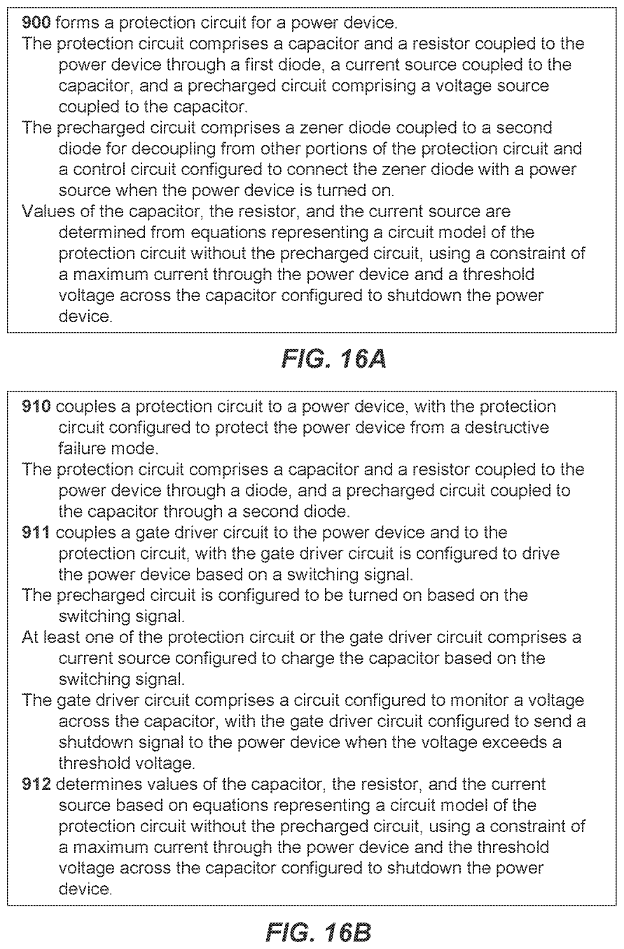

FIGS. 16A-16B show flow charts for forming a protection circuit having a Zener diode precharged circuit according to some embodiments. FIG. 16A shows a flow chart for forming a protection circuit with a Zener diode precharged circuit. Operation 1600 forms a protection circuit for a power device. The protection circuit comprises a capacitor and a resistor coupled to the power device through a first diode, a current source coupled to the capacitor, and a precharged circuit comprising a voltage source coupled to the capacitor.

The precharged circuit comprises a Zener diode coupled to a second diode for decoupling from other portions of the protection circuit and a control circuit configured to connect the Zener diode with a power source when the power device is turned on.

Values of the capacitor, the resistor, and the current source are determined from equations representing a circuit model of the protection circuit without the precharged circuit, using a constraint of a maximum current through the power device and a threshold voltage across the capacitor configured to shutdown the power device.

FIG. 16B shows a method for forming a protection circuit with a Zener diode precharged circuit. Operation 1610 couples a protection circuit to a power device, with the protection circuit configured to protect the power device from a destructive failure mode. The protection circuit comprises a capacitor and a resistor coupled to the power device through a diode, and a precharged circuit coupled to the capacitor through a second diode.

Operation 1611 couples a gate driver circuit to the power device and to the protection circuit, with the gate driver circuit is configured to drive the power device based on a switching signal. The precharged circuit is configured to be turned on based on the switching signal. At least one of the protection circuit or the gate driver circuit comprises a current source configured to charge the capacitor based on the switching signal.

The gate driver circuit comprises a circuit configured to monitor a voltage across the capacitor, with the gate driver circuit configured to send a shutdown signal to the power device when the voltage exceeds a threshold voltage.

Operation 1612 determines values of the capacitor, the resistor, and the current source based on equations representing a circuit model of the protection circuit without the precharged circuit, using a constraint of a maximum current through the power device and the threshold voltage across the capacitor configured to shutdown the power device.

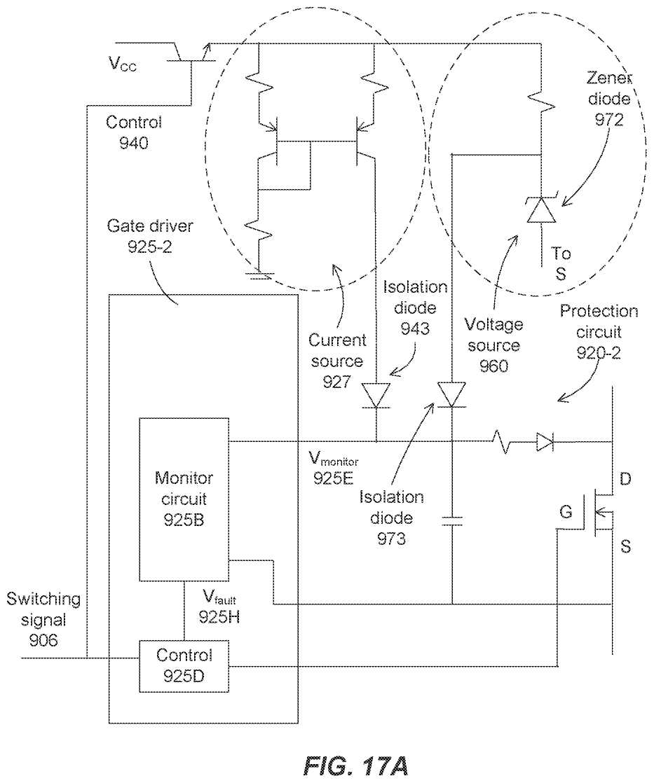

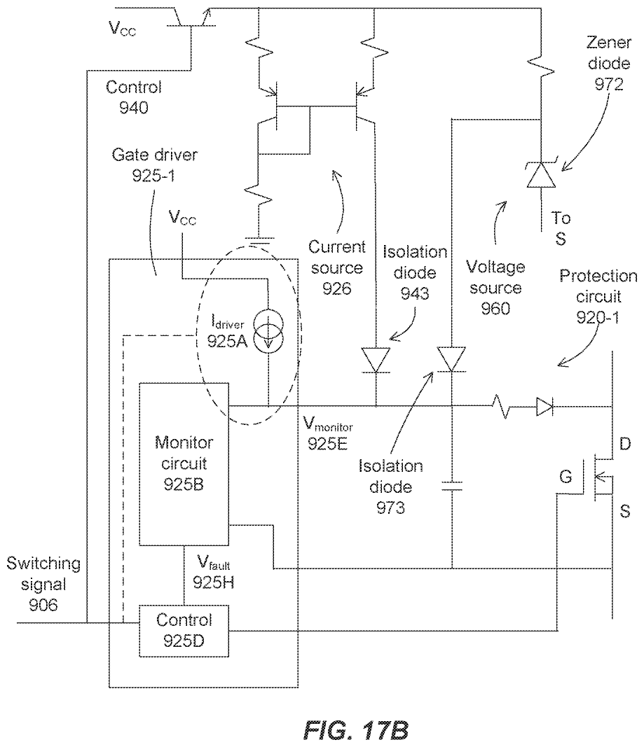

FIGS. 17A-17B illustrate configurations for a protection circuit together with a gate driver circuit for a power device according to some embodiments. FIG. 17A shows a configuration for a protection circuit 920-2 having a current source together with a gate driver circuit 925-2 not having a current source. The protection circuit includes a blanking capacitor and a blanking resistor coupled to the power device through one or more diodes (one diode is shown). The protection circuit also includes a total current source 927 having a current mirror configuration. The current source 927 is coupled to the blanking capacitor through a one-way isolation circuit such as a diode 943, so that the current source does not affect the overcurrent fault detection function of the protection circuit. The current source 927 is controlled by a controllable switch, under a control signal 940 configured to turn on the current source when the power device is turned on. For example, the control signal 940 can be coupled to the switching signal 906.

The gate driver circuit 925-2 includes a monitor circuit 925B configured to monitor a voltage Vₘₒₙᵢₜₒᵣ 925E from the blanking capacitor. The monitor circuit is configured to generate a fault signal V_{fault} 925H to a control circuit 925D when the monitor voltage Vₘₒₙᵢₜₒᵣ 925E exceeds a threshold voltage Vₜₕ. The control circuit 925D is configured to send a shut down signal to the power device when receiving the fault signal V_{fault}.

In some embodiments, the gate driver circuit 925-2 does not have an internal current source. Thus, the current source 927 of the protection circuit is a total current source, determined from the circuit model of the protection circuit, together with the values for the blanking capacitor and resistor.

The protection circuit also includes a precharged circuit 960 based on a Zener diode configuration 972. The precharged circuit 960 is coupled to the blanking capacitor through a one-way isolation circuit such as a diode 973, so that the precharged circuit does not affect the overcurrent fault detection function of the protection circuit. The precharged circuit 960 is controlled by the controllable switch in the current source 927. to turn on the precharged circuit when the power device is turned on.

FIG. 17B shows a configuration for a protection circuit 920-1 having a current source together with a gate driver circuit 925-1 also having another current source. The gate driver circuit 925-1 includes a monitor circuit 925B and a control circuit 925D. The gate driver circuit 925-1 also includes an internal current source I_{driver} 925A. For example, the gate driver circuit 920-1 can be configured with the internal current source, for example, as a gate driver integrated circuit for Si IGBT.

The protection circuit includes an additional current source 926 having a current mirror configuration. The additional current source 926 is coupled to the blanking capacitor through a one-way isolation circuit such as a diode 943. The additional current source 926 is controlled by a controllable switch, under a control signal 940.

Thus, a sum of the internal current source 925A and the additional current source 926 is equal to a total current source 927 determined from the circuit model of the protection circuit. In other words, the value of the additional current source 926 is determined based on the total current source 927 and the internal current source 925A.

The protection circuit also includes a precharged circuit 960 based on a Zener diode configuration 972 together with an one-way isolation circuit such as a diode 973. The precharged circuit 960 is controlled by the controllable switch in the current source 927.

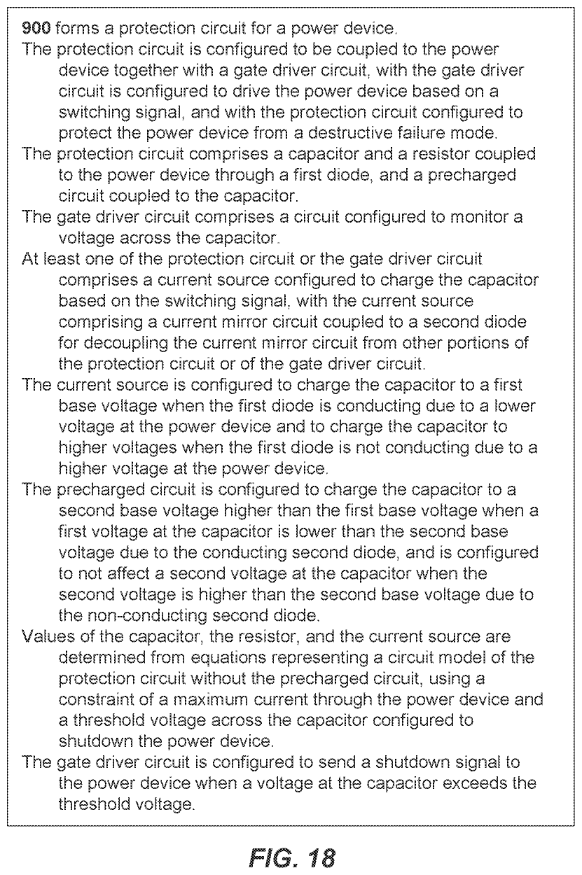

FIG. 18 illustrates a flow chart for forming a protection circuit together with a gate driver circuit for a power device according to some embodiments. Operation 1800 forms a protection circuit for a power device. The protection circuit is configured to be coupled to the power device together with a gate driver circuit, with the gate driver circuit is configured to drive the power device based on a switching signal, and with the protection circuit configured to protect the power device from a destructive failure mode. The protection circuit comprises a capacitor and a resistor coupled to the power device through a first diode, and a precharged circuit coupled to the capacitor.

The gate driver circuit comprises a circuit configured to monitor a voltage across the capacitor. At least one of the protection circuit or the gate driver circuit comprises a current source configured to charge the capacitor based on the switching signal, with the current source comprising a current mirror circuit coupled to a second diode for decoupling the current mirror circuit from other portions of the protection circuit or of the gate driver circuit.

The current source is configured to charge the capacitor to a first base voltage when the first diode is conducting due to a lower voltage at the power device and to charge the capacitor to higher voltages when the first diode is not conducting due to a higher voltage at the power device.

The precharged circuit is configured to charge the capacitor to a second base voltage higher than the first base voltage when a first voltage at the capacitor is lower than the second base voltage due to the conducting second diode, and is configured to not affect a second voltage at the capacitor when the second voltage is higher than the second base voltage due to the non-conducting second diode.

Values of the capacitor, the resistor, and the current source are determined from equations representing a circuit model of the protection circuit without the precharged circuit, using a constraint of a maximum current through the power device and a threshold voltage across the capacitor configured to shutdown the power device.

The gate driver circuit is configured to send a shutdown signal to the power device when a voltage at the capacitor exceeds the threshold voltage.

### General Disclaimer

For convenience, “top”, “bottom”, “above”, “below” and similar descriptors are used merely as points of reference in the description, and while corresponding to the general orientation of the illustrated system during operation, are not to be construed to limit the orientation of the system during operation or otherwise.

As employed herein, the statement that two or more parts are “coupled” together shall mean that the parts are joined or connected together either directly or through one or more intermediate parts.

As employed herein, the term “switch” means any switches suitable for use in an electrical circuit. The term includes both mechanical type switches, such as switches which physically separate contacts of the switch, and solid-state type switches, such as transistors.

When a term such as “about”, “approximately”, or “substantial” is applied to a particular value, e.g. “about perpendicular” or “substantially parallel”, the value, according to the present specification, is interpreted as deviating less than 20%, less than 10%, less than 5%, or less than 2%, of the value.

What is claimed is:

1. A protection circuit for a power device comprising components assembled to protect the power device from a destructive failure mode,
wherein values of the components are determined from a circuit model of the protection circuit, with the circuit model comprising parameters of the power device, and with the determination comprising using constraints of a maximum current through the power device and a threshold voltage of the power device configured to trigger a shutdown of the power device.

2. The protection circuit of claim 1
wherein the values of the components are determined to provide a protection circuit being independent of a current gradient through the power device.

3. The protection circuit of claim 1,
wherein the protection circuit comprises a capacitor coupled to the power device through a resistor and a diode, and a current source configured to charge the capacitor to the threshold voltage when the power device is at the destructive failure mode.

4. A protection circuit for a power device, with the power device driven by a gate driver circuit, the protection circuit comprising:
a capacitor and a resistor coupled to the power device through a diode,
wherein the gate driver circuit is configured to drive the power device based on a switching signal, with the gate driver circuit comprising a circuit configured to monitor a voltage across the capacitor, and with the gate driver circuit configured to send a shutdown signal to the power device when the voltage exceeds a threshold voltage,
wherein at least one of the protection circuit or the gate driver circuit comprises a current source configured to charge the capacitor based on the switching signal,
wherein values of the capacitor, the resistor, and the at least a current source are determined from a circuit model of the protection circuit, with the circuit model comprising parameters of the power device, and with the determination comprising using constraints of a maximum current through the power device and the threshold voltage.

5. The protection circuit of claim 4,
wherein only the protection circuit comprises the at least a current source.

6. The protection circuit of claim 4,
wherein the at least a current source comprises a first current source in the protection circuit and a second current source in the gate driver circuit,
wherein the value of the at least a current source comprises a total value of the first and second current sources.

7. The protection circuit of claim 4,
wherein the at least a current source comprising a current mirror circuit coupled to a second diode for decoupling from other portions of the protection circuit or of the gate driver circuit.

8. The protection circuit of claim 4,
wherein the values of the capacitor, the resistor, and the at least a current source are determined to provide the protection circuit to be independent of a current gradient.

9. The protection circuit of claim 4,
wherein the maximum current is selected to be 150 A or smaller,
wherein the threshold voltage is selected to be 10 V or smaller.

10. The protection circuit of claim 4,
wherein the parameters of the power device comprise a parasitic inductance and an ON resistance of the power device, determined from a datasheet of the power device or from a characterization of the power device.

11. The protection circuit of claim 4,
wherein a value of the capacitor is selected to be in a vicinity of 220 pF for improving noise tolerance.

12. The protection circuit of claim 4, further comprising:
wherein the values of the capacitor, the resistor, and the at least a current source are determined based on relationships of the resistor, the capacitor, the parameters of the power device comprising a parasitic inductance and an ON resistance, the maximum current through the power device, the threshold voltage, and the diode.

13. The protection circuit of claim 4,
wherein the values of the capacitor and the resistor are determined with the product of the resistor and the capacitor proportional to a ratio of a parasitic inductance and an ON resistance of the power device.

14. The protection circuit of claim 4,
wherein the value of the at least a current source is determined with the at least a current source proportional to a ratio of a numerator value and a denominator value, with the numerator value being a difference between the threshold voltage and a sum of the diode and a product of the maximum current and an ON resistance of the power device, and with the denominator value being the resistor.

15. The protection circuit of claim 4, further comprising
a precharged circuit coupled to the capacitor through a one-way component,
wherein the circuit model of the protection circuit is configured to exclude the precharged circuit due to the one way component.

16. A protection circuit for a power device, with the power device driven by a gate driver circuit, the protection circuit comprising:
a capacitor and a resistor coupled to the power device through a first diode,
a precharged circuit coupled to the capacitor through a one-way component,
wherein the gate driver circuit is configured to drive the power device based on a switching signal, with the gate driver circuit comprising a circuit configured to monitor a voltage across the capacitor, and with the gate driver circuit configured to send a shutdown signal to the power device when the voltage exceeds a threshold voltage,
wherein at least one of the protection circuit or the gate driver circuit comprises a current source configured to charge the capacitor based on the switching signal,
wherein values of the capacitor, the resistor, and the at least a current source are determined from a circuit model of the protection circuit, with the precharged circuit decoupled from the circuit model due to the one way component, with the circuit model comprising parameters of the power device, and with the determination comprising using constraints of a maximum current through the power device and the threshold voltage.

17. The protection circuit of claim 16,
wherein the at least a current source is configured to charge the capacitor to a first base voltage when the power device is in a normal operation and to charge the capacitor to higher voltage when the power device is at a fault operation.

18. The protection circuit of claim 16,
wherein the one way component comprises a second diode.

19. The protection circuit of claim 16,
wherein the precharged circuit comprises a voltage source.

20. The protection circuit of claim 16,
wherein the precharged circuit comprises a Zener diode coupled to a power source controlled by the switching signal, with the Zener diode configured to provide a constant voltage to the capacitor.
